(19) United States
(12) Patent Application Publication
(10) Pub. No.: US 2026/0150727 A1
(43) Pub. Date: May 28, 2026

(54) SEMICONDUCTOR PACKAGE

(71) Applicant: Samsung Electronics Co., Ltd., Suwon-si (KR)

(72) Inventor: Juhyeon OH, Suwon-si (KR)

(73) Assignee: Samsung Electronics Co., Ltd., Suwon-si (KR)

(21) Appl. No.: 19/221,952

(22) Filed: May 29, 2025

(30) Foreign Application Priority Data
Nov. 27, 2024 (KR) 10-2024-0172769

(51) Int. Cl. H01L 23/00; H01L 23/31; H01L 23/538; H01L 25/065; H10B 80/00

(52) U.S. Cl. CPC H10W 70/635; H10B 80/00; H10W 70/611; H10W 74/117; H10W 90/00; H10W 72/952; H10W 74/15; H10W 90/722; H10W 90/732; H10W 90/792; H10W 90/794

(57) ABSTRACT

A semiconductor package capable of implementing high bandwidth, high speed, and/or wide input/output and increasing yield is provided. The semiconductor package includes an interposer, a first semiconductor device on the interposer, and at least one second semiconductor device on the interposer and connected to the interposer through hybrid copper bonding (HCB), the at least one second semiconductor device adjacent to the first semiconductor device, the at least one second semiconductor device including a base chip bonded to the interposer through HCB, a chip stack structure on the base chip and connected to the base chip through a first connection terminal, a plurality of memory chips stacked in the chip stack structure, and an inner sealant on the base chip and sealing the chip stack structure.

### CROSS-REFERENCE TO RELATED APPLICATION

This application is based on and claims priority under 35 U.S.C. § 119 to Korean Patent Application No. 10-2024-0172769, filed on Nov. 27, 2024, in the Korean Intellectual Property Office, the disclosure of which is incorporated by reference herein in its entirety.

### BACKGROUND

The inventive concepts relate to semiconductor packages, and more particularly, to semiconductor packages including a chip stack structure in which semiconductor chips are stacked.

With the rapid development of the electronics industry and users'needs, electronic devices have become compact and light. With the compactness and lightness of electronic devices, semiconductor packages used in the electronic devices have also been compact and light and it is desirable to have high performance, high capacity, and high reliability. To realize compactness, lightness, high performance, high capacity, and high reliability, there is ongoing research and development of semiconductor chips including a through-silicon via (TSV) structure and of semiconductor packages having a chip stack structure in which these semiconductor chips are stacked.

### SUMMARY

The inventive concepts provide semiconductor packages capable of implementing high bandwidth, high speed, and/or wide input/output, thereby increasing yield.

Also, the problems to be solved by the technical ideas of the present inventive concepts are not limited to those mentioned above, and the inventive concepts can be clearly understood by those skilled in the art from the description below.

According to some aspects of the inventive concepts, there is provided a semiconductor package including an interposer, a first semiconductor device on the interposer, and at least one second semiconductor device on the interposer and connected to the interposer through hybrid copper bonding (HCB), the at least one second semiconductor device adjacent to the first semiconductor device, the at least one second semiconductor device including a base chip bonded to the interposer through HCB, a chip stack structure on the base chip and connected to the base chip through a first connection terminal, a plurality of memory chips stacked in the chip stack structure, and an inner sealant on the base chip and sealing the chip stack structure.

According to some aspects of the inventive concepts, there is provided a semiconductor package including an interposer, a first semiconductor device on the interposer and connected to the interposer through a first connection terminal, at least one second semiconductor device on the interposer and connected to the interposer through HCB, the at least one second semiconductor device adjacent to the first semiconductor device, and an external sealant on the interposer and sealing the first semiconductor device and the at least one second semiconductor device, the at least one second semiconductor device including a base chip bonded to the interposer through HCB, a chip stack structure on the base chip and connected to the base chip through a second connection terminal, a plurality of memory chips stacked in the chip stack structure, an adhesive layer between the base chip and the chip stack structure, and an inner sealant on the base chip and sealing the chip stack structure and the adhesive layer.

According to some aspects of the inventive concepts, there is provided a semiconductor package including a package substrate, an interposer on the package substrate, a first semiconductor device on the interposer and connected to the interposer through a first connection terminal, and at least one second semiconductor device on the interposer and connected to the interposer through HCB, the at least one second semiconductor device adjacent to the first semiconductor device, the at least one second semiconductor device including a base chip bonded to the interposer through HCB, a chip stack structure arranged on the base chip and connected to the base chip through a second connection terminal, a plurality of memory chips are stacked in the chip stack structure, and an inner sealant on the base chip and sealing the chip stack structure.

According to some aspects of the inventive concepts, there is provided a method of manufacturing a semiconductor package including forming an interposer substrate on a wafer including forming a through electrode in an initial body layer, and forming an interposer pad on an initial wiring layer on the initial body layer; forming a semiconductor package structure including mounting first and second semiconductor devices on the initial interposer substrate, and forming an outer sealant on side surfaces of the first and second semiconductor devices; forming external connection terminals on the interposer substrate including removing a lower portion of the interposer substrate exposing the through electrode and forming an interposer lower pad electrically connected to the through electrode; singulating the semiconductor package structure from the wafer; and mounting the semiconductor package structure on a package substrate.

According to some aspects of the inventive concepts, the method of manufacturing the semiconductor package may further include forming the first semiconductor device including connecting a base chip to memory chips through hybrid copper bonding.

### BRIEF DESCRIPTION OF THE DRAWINGS

Example embodiments will be more clearly understood from the following detailed description taken in conjunction with the accompanying drawings in which:

FIGS. 1A and 1B are cross-sectional views of a semiconductor package according to an embodiment;

FIGS. 2A and 2B are cross-sectional views of a semiconductor package according to an embodiment;

FIG. 3 is a cross-sectional view of a semiconductor package according to an embodiment;

FIG. 4 is a cross-sectional view of a system package according to an embodiment;

FIGS. 5A and 5B are respectively a perspective view and a cross-sectional view of a system package according to an embodiment;

FIGS. 6A to 6E are schematic cross-sectional views of stages in a method of manufacturing a system package, according to an embodiment;

FIGS. 7A to 7H are schematic cross-sectional views of stages in a method of manufacturing a semiconductor package, according to an embodiment; and

FIGS. 8A to 8E are schematic cross-sectional views of stages in a method of manufacturing a chip stack structure, according to an embodiment.

### DETAILED DESCRIPTION OF THE EMBODIMENTS

Hereinafter, embodiments will be described in detail with reference to the accompanying drawings. In the drawings, like reference characters denote like elements, and redundant descriptions thereof will be omitted.

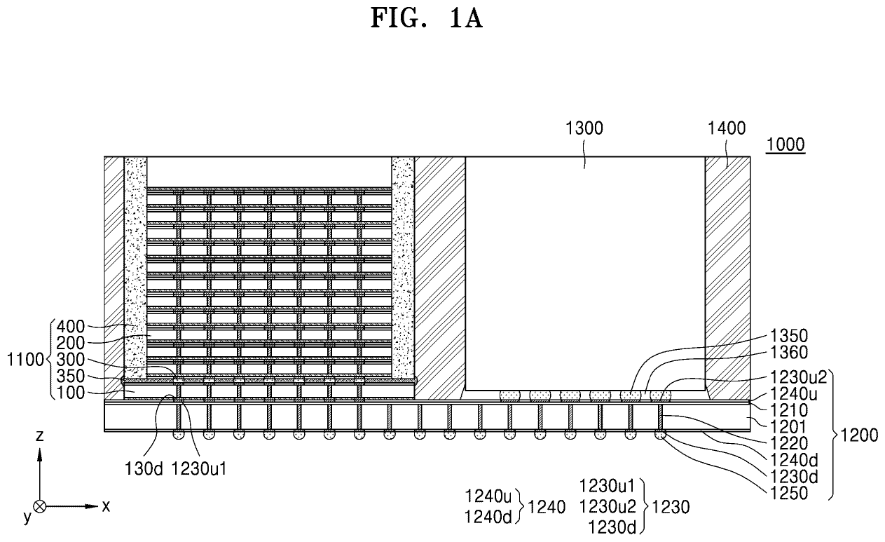

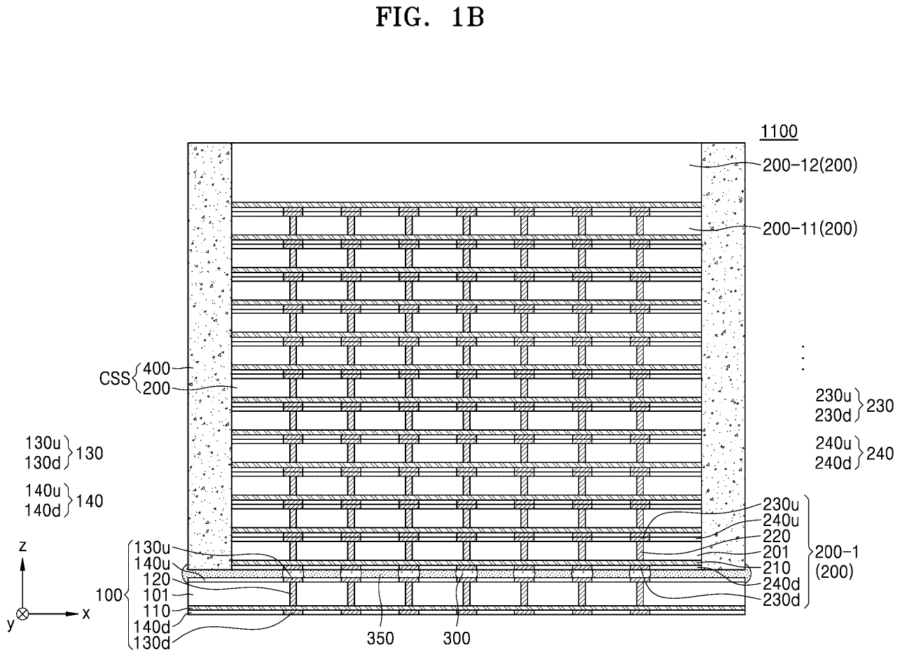

FIGS. 1A and 1B are cross-sectional views of a semiconductor package according to an embodiment. FIG. 1B shows in detail a first semiconductor device of the semiconductor package of FIG. 1A.

Referring to FIGS. 1A and 1B, a semiconductor package 1000 of some example embodiments may include a first semiconductor device 1100, an interposer 1200, a second semiconductor device 1300, and an outer sealant 1400.

The first semiconductor device 1100 may be mounted on the interposer 1200. As seen in FIG. 1A, the first semiconductor device 1100 may be arranged on the left portion of the interposer 1200 in an x-direction. However, the position of the first semiconductor device 1100 is not limited thereto.

The first semiconductor device 1100 may include a high-bandwidth memory (HBM) package. In detail, the first semiconductor device 1100 may include a base chip 100, memory chips 200, a first connection terminal 300, and an inner sealant 400.

The base chip 100 may include a first body layer 101, a first active layer 110, a first through electrode 120, a first pad 130, and a first protective layer 140. The size of the base chip 100 may be greater than the size of each of the memory chips 200 arranged above the base chip 100, as shown in FIG. 1B. However, the size of the base chip 100 is not limited thereto. In some example embodiments, the base chip 100 may have the same or substantially the same size as each of the memory chips 200.

For example, the first body layer 101 may include a semiconductor element, such as silicon (Si) and/or germanium (Ge). The first body layer 101 may include a compound semiconductor, such as silicon carbide (SiC), gallium arsenide (GaAs), indium arsenide (InAs), and/or indium phosphide (InP). The first body layer 101 may have a silicon-on-insulator (SOI) structure. For example, the first body layer 101 may include a buried oxide (BOX) layer. The first body layer 101 may include a conductive region, e.g., an impurity-doped well or a structure such as an impurity-doped source/drain region. The first body layer 101 may include various isolation structures including a shallow trench isolation (STI) structure.

The first active layer 110 may include an integrated circuit layer and a wiring layer on the integrated circuit layer. The integrated circuit layer may include various kinds of devices. For example, the integrated circuit layer may include various kinds of active devices and/or passive devices, such as a transistor, memory devices, logic devices, a system large scale integration (LSI), a complementary metal-oxide-semiconductor (CMOS) image sensor (CIS), and a micro-electro-mechanical system (MEMS).

For example, a transistor may include a bipolar junction transistor (BJT) or a field-effect transistor (FET), such as a planar FET or a FinFET. For example, memory devices may include volatile memory devices, such as dynamic random access memory (DRAM) devices or static RAM (SRAM) devices, or non-volatile memory devices, such as flash memory devices, phase-change RAM (PRAM) devices, magnetoresistive RAM (MRAM) devices, ferroelectric RAM (FeRAM) devices, and/or resistive RAM (RRAM) devices.

For example, logic devices may include an AND gate, a NAND gate, an OR gate, a NOR gate, an exclusive OR (XOR) gate, an exclusive NOR (XNOR) gate, an inverter (INV), an adder (ADD), a delay (DLY), a filter (FIL), a multiplexer (MXT/MXIT), an OR/AND/inverter (OAI) gate, an AND/OR (AO) gate, an AND/OR/inverter (AOI) gate, a D flip-flop, a reset flip-flop, a master-slave flip-flop, a latch, a counter, or a buffer. Logic devices may perform various kinds of signal processing, such as analog signal processing, analog-to-digital conversion, and control.

The wiring layer may connect at least two devices to each other, connect devices to the conductive region of the first body layer 101, or connect devices to the first pad 130, e.g., a first lower pad 130d. The wiring layer may also connect the first through electrode 120 to the first lower pad 130d. For example, the wiring layer may include a wiring insulating layer, wires, and a contact or via. In the first semiconductor device 1100 of the semiconductor package 1000 of some example embodiments, the first active layer 110 may be arranged below the first body layer 101 and the first through electrode 120. However, in some example embodiments, the first active layer 110 may be arranged above the first body layer 101 and the first through electrode 120.

In the first semiconductor device 1100 of the semiconductor package 1000 of some example embodiments, the base chip 100 may include a plurality of logic devices in the integrated circuit layer of the first active layer 110. The base chip 100 may be arranged below the memory chips 200 and may combine signals from the memory chips 200 and transmit a result of the combination to the outside. The base chip 100 may also transmit a signal and power from the outside to the memory chips 200. Accordingly, the base chip 100 may be referred to as a buffer chip or an interface chip.

In some example embodiments, the base chip 100 may include a controller that controls signal transmission between the memory chips 200 and an external device. When the base chip 100 includes the controller, the base chip 100 may be referred to as a logic chip or a control chip. In some example embodiments, the base chip 100 may include logic devices for arithmetic operations. The base chip 100 may also include a power management integrated circuit (PMIC) that manages power or a clock. When the base chip 100 is referred to as a buffer chip, the memory chips 200 may be referred to as core chips.

In the first semiconductor device 1100 of the semiconductor package 1000 of some example embodiments, the base chip 100 is not limited to a buffer chip or a logic chip. For example, the base chip 100 may include a plurality of memory devices in the integrated circuit layer of the first active layer 110. Accordingly, the base chip 100 may include a memory chip.

The first through electrode 120 may extend from the top to the bottom of the first body layer 101 through the first body layer 101. In some example embodiments, the first through electrode 120 may extend into the first active layer 110. In the first semiconductor device 1100 of the semiconductor package 1000 of some example embodiments, the first body layer 101 may include Si, and accordingly, the first through electrode 120 may correspond to a through-silicon via (TSV).

The first through electrode 120 may have a pillar shape and include a barrier film on an outer surface thereof and a buried conductive layer therein. The barrier film may include at least one material selected from the group consisting of Ti, TiN, Ta, TaN, Ru, Co, Mn, WN, Ni, and NiB. The buried conductive layer may include at least one material selected from the group consisting of Cu, Cu alloys, such as CuSn, CuMg, CuNi, CuZn, CuPd, CuAu, CuRe, and/or CuW, W, W alloys, Ni, Ru, and/or Co. An insulating layer may be between the first through electrode 120 and the first body layer 101 or between the first through electrode 120 and the first active layer 110. For example, the insulating layer may include an oxide film, a nitride film, a carbide film, a polymer, or a combination thereof.

The first pad 130 may include a first upper pad 130u and a first lower pad 130d. The first upper pad 130u may be arranged on the top surface of the first body layer 101. The first upper pad 130u may be connected to the first through electrode 120. The first connection terminal 300 may be arranged on the first upper pad 130u.

The first lower pad 130d may be arranged on the bottom surface of the first active layer 110 and connected to wires of the wiring layer of the first active layer 110. The first lower pad 130d may be connected to the first through electrode 120 through the wiring layer. The first lower pad 130d may be connected to an interposer pad 1230, e.g., a first interposer upper pad 1230u1, of the interposer 1200 through hybrid copper bonding (HCB). HCB is described in detail below in the description of the connection between the first semiconductor device 1100 and the interposer 1200.

For example, the first pad 130 may include at least one selected from the group consisting of aluminum (Al), copper (Cu), nickel (Ni), tungsten (W), platinum (Pt), and gold (Au). In the first semiconductor device 1100 of the semiconductor package 1000 of some example embodiments, the first pad 130 of the base chip 100 may include Cu. However, the material of the first pad 130 is not limited to Cu.

The first protective layer 140 may be arranged on the bottom and top surfaces of the base chip 100. For example, the first protective layer 140 may include a first upper protective layer 140u and a first lower protective layer 140d. The first upper protective layer 140u may be arranged on the top surface of the first body layer 101. The first upper pad 130u may pass through at least a portion of the first upper protective layer 140u. For example, the first upper pad 130u may be connected to the first through electrode 120 through at least a portion of the first upper protective layer 140u.

The first lower protective layer 140d may be arranged on the bottom surface of the first active layer 110. The first lower pad 130d may pass through at least a portion of the first lower protective layer 140d. For example, a thick pad metal layer may be arranged in the first lower protective layer 140d, and the first lower pad 130d may pass through a portion of the first lower protective layer 140d to be connected to the pad metal layer. For example, the pad metal layer may include aluminum (Al). Accordingly, the first lower pad 130d may be connected to wires of the wiring layer through the pad metal layer. The first lower pad 130d may also be connected to the first through electrode 120 through wires of the wiring layer.

For example, the first protective layer 140 may include an oxide film, a nitride film, a carbide film, a polymer, or a combination thereof. However, the material of the first protective layer 140 is not limited thereto. The first protective layer 140 may have a single-film structure or a multi-film structure.

The memory chips 200 may be stacked on the base chip 100. In the first semiconductor device 1100 of the semiconductor package 1000 of some example embodiments, twelve memory chips 200, e.g., first to twelfth memory chips 200-1 to 200-12, may be stacked on the base chip 100. However, the number of memory chips 200 stacked on the base chip 100 is not limited to twelve. For example, two to eleven memory chips 200 or at least 13 memory chips 200 may be stacked on the base chip 100.

In the first semiconductor device 1100 of the semiconductor package 1000 of some example embodiments, the number of memory chips 200 may be 4n, where “n” is a natural number. Accordingly, the first semiconductor device 1100 may include memory chips 200 in a multiple of 4, e.g., four, eight, or twelve memory chips 200. The memory chips 200 may be divided into groups, and four memory chips 200 in each group may have the same stack ID and may be tested and operated together. For example, when the first semiconductor device 1100 includes twelve memory chips 200, the first to fourth memory chips 200-1 to 200-4 may have a first stack ID, the fifth to eighth memory chips 200-5 to 200-8 may have a second stack ID, and the ninth to twelfth memory chips 200-9 to 200-12 may have a third stack ID. However, the first semiconductor device 1100 is not limited to the memory chips 200 in a multiple of 4 and stack IDs corresponding thereto. For example, the first semiconductor device 1100 may include the memory chips 200 in a multiple of 2 and stack IDs corresponding thereto or in a multiple of 8 and stack IDs corresponding thereto.

The first to twelfth memory chips 200-1 to 200-12 may have the same or substantially the same horizontal size and internal structure. However, the topmost memory chip 200, e.g., the twelfth memory chip 200-12, may not include a through electrode. As shown in FIGS. 1A and 1B, the twelfth memory chip 200-12 may be thicker than the other memory chips 200. In some example embodiments, the total height of the first semiconductor device 1100 may be adjusted by adjusting the thickness of the twelfth memory chip 200-12. For convenience, the specific structure of each of the memory chips 200 is described using the first memory chip 200-1 below.

The first memory chip 200-1 may include a second body layer 201, a second active layer 210, a second through electrode 220, a second pad 230, and a second protective layer 240. The description of the second body layer 201 is the same as that of the first body layer 101 of the base chip 100.

The second active layer 210 may include a plurality of memory devices. For example, the second active layer 210 may include volatile memory devices, such as DRAM devices or SRAM devices, or non-volatile memory devices, such as PRAM devices, MRAM devices, ReRAM devices, or RRAM devices. For example, the first memory chip 200-1 may include DRAM devices in the second active layer 210. Accordingly, the first memory chip 200-1 may correspond to a DRAM chip. As described above, the first semiconductor device 1100 may correspond to an HBM package, and the first memory chip 200-1 may correspond to a DRAM chip for HBM.

The second through electrode 220 may pass through the second body layer 201. The second through electrode 220 may extend into the second active layer 210. For example, the first memory chip 200-1 may be divided into a cell region and a pad region. When the second through electrode 220 is formed only in the pad region, the second through electrode 220 may pass through the second body layer 201 and extend into the second active layer 210. The other description of the second through electrode 220 is the same as that of the first through electrode 120 of the base chip 100.

The second pad 230 may include a second lower pad 230d arranged on the bottom surface of the second active layer 210 and a second upper pad 230u arranged on the top surface of the second body layer 201. The second lower pad 230d on the bottom surface of the second active layer 210 may be connected to wires of the wiring layer of the second active layer 210. The second lower pad 230d may be connected to the second through electrode 220 through the wiring layer. The second upper pad 230u on the top surface of the second body layer 201 may be connected to the second through electrode 220. The description of the material of the second pad 230 is the same as that of the first pad 130 of the base chip 100.

The second protective layer 240 may include a second lower protective layer 240d arranged on the bottom surface of the second active layer 210 and a second upper protective layer 240u arranged on the top surface of the second body layer 201. The description of the second protective layer 240 is the same as that of the first protective layer 140 of the base chip 100.

The second upper pad 230u may pass through at least a portion of the second upper protective layer 240u. For example, the second upper pad 230u may pass through at least a portion of the second upper protective layer 240u to be connected to the second through electrode 220. The second lower pad 230d may pass through at least a portion of the second lower protective layer 240d. For example, the second lower pad 230d may pass through at least a portion of the second lower protective layer 240d to be connected to a pad metal layer and may be connected to the wires of the wiring layer through the pad metal layer. The second lower pad 230d may also be connected to the second through electrode 220 through wires of the wiring layer.

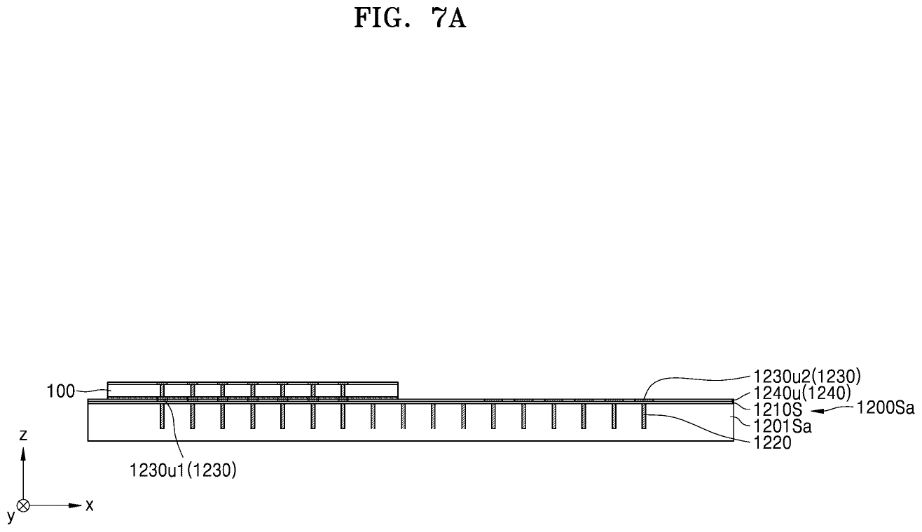

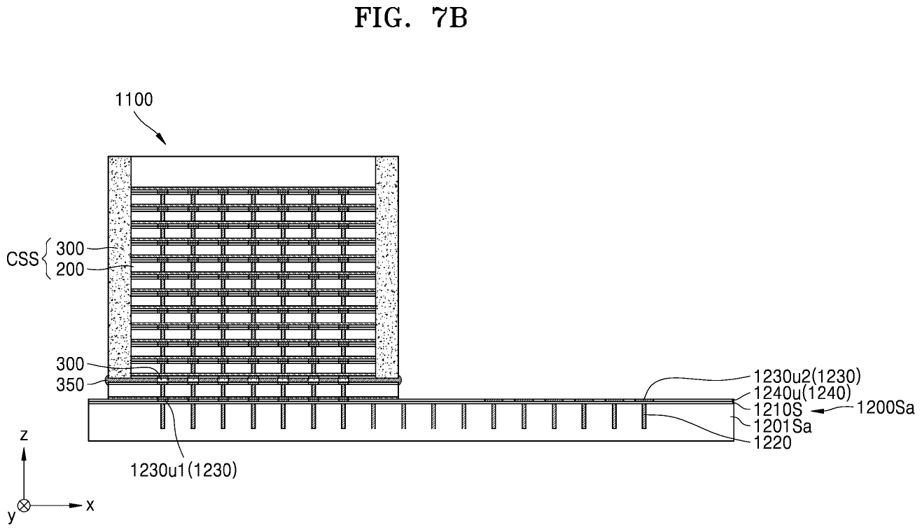

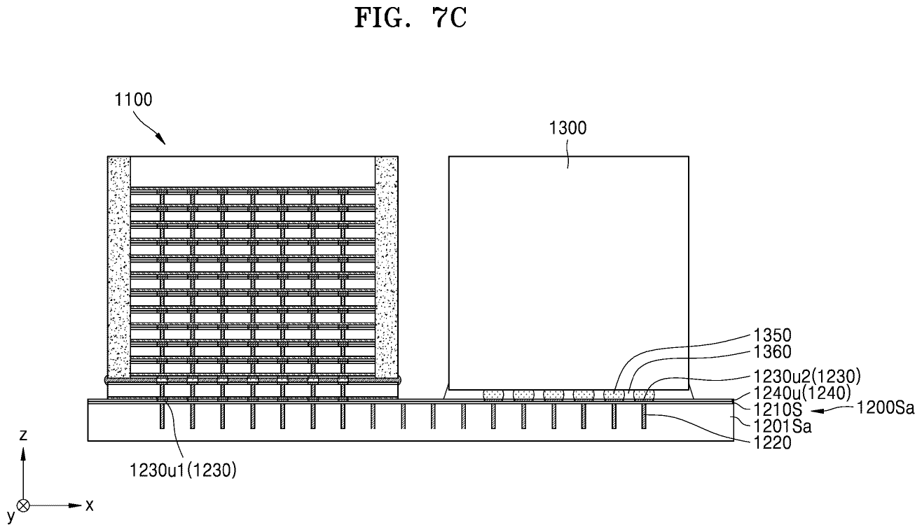

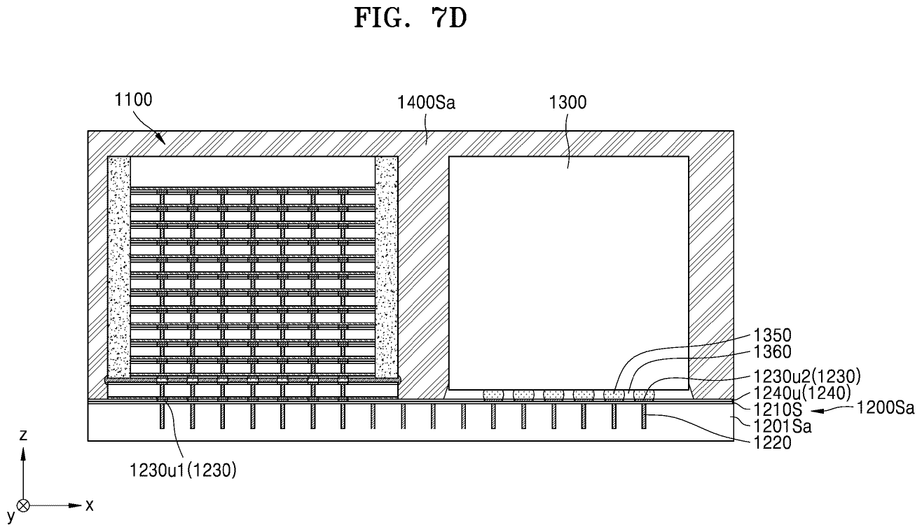

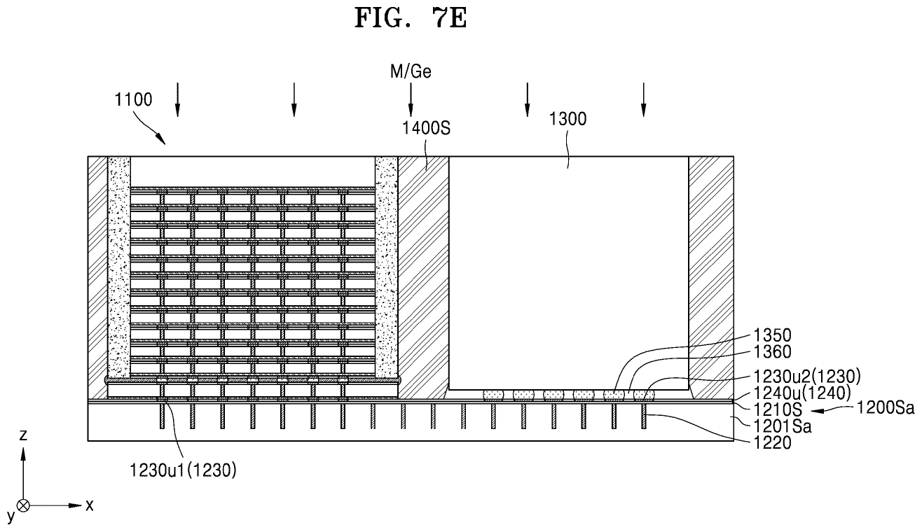

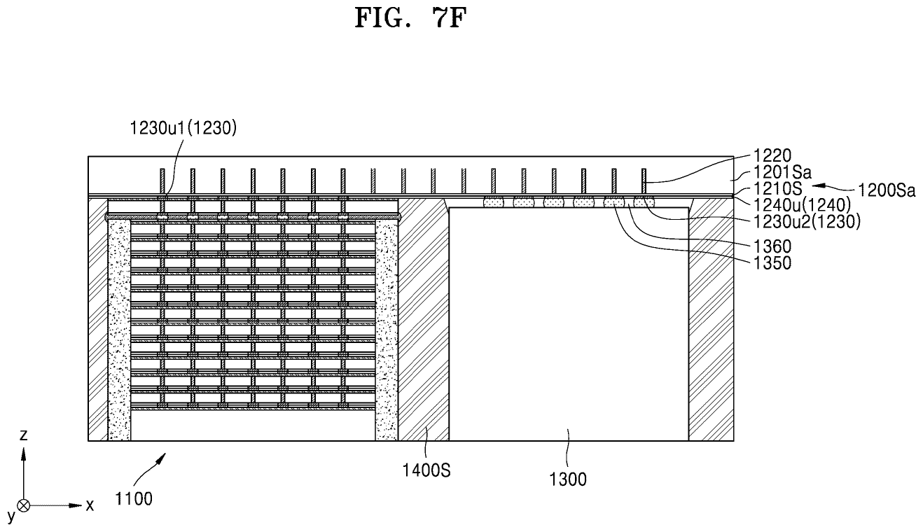

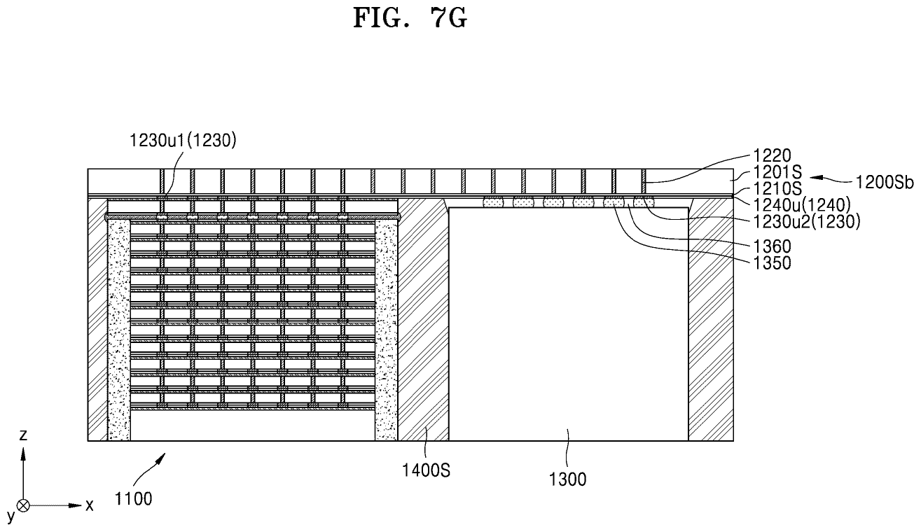

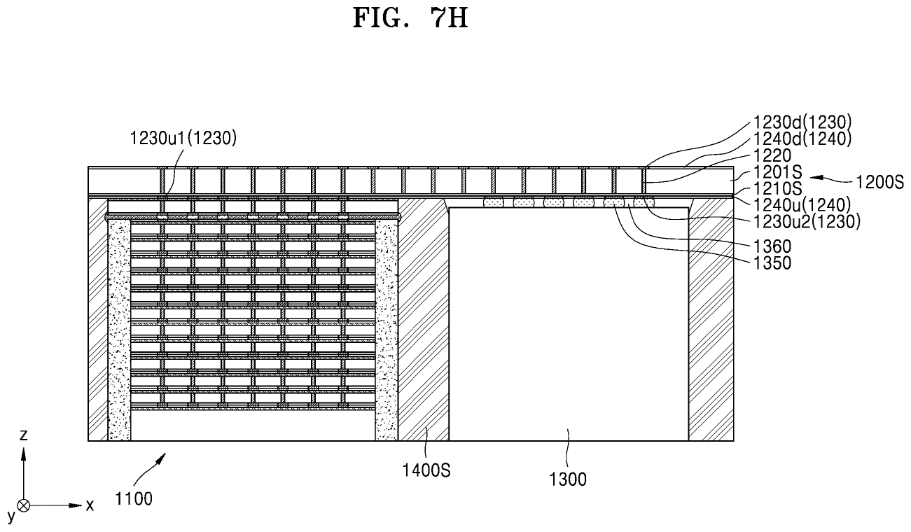

In the semiconductor package 1000 of some example embodiments, the first semiconductor device 1100 may be stacked on the interposer 1200 through HCB. For example, the base chip 100 of the first semiconductor device 1100 may be stacked on the interposer 1200 through HCB. HCB may refer to a combination of pad-to-pad bonding and insulator-to-insulator bonding. In general, pads include Cu, and thus, pad-to-pad bonding is referred to as Cu-to-Cu bonding. Specifically, the first interposer upper pad 1230u1 of the interposer 1200 may be bonded to the first lower pad 130d of the base chip 100, and an upper protective layer 1240u of the interposer 1200 may be bonded to the first lower protective layer 140d of the base chip 100 so that HCB may be formed between the base chip 100 and the interposer 1200. HCB is described in detail when a method of manufacturing a semiconductor package is described with reference to FIGS. 7A to 7H below.

In the first semiconductor device 1100 of the semiconductor package 1000 of some example embodiments, the first memory chip 200-1 among the memory chips 200 may be stacked on the base chip 100 through the first connection terminal 300. For example, the first connection terminal 300 may be between the second lower pad 230d at the bottom of the first memory chip 200-1 and the first upper pad 130u at the top of the base chip 100. The first connection terminal 300 may be connected to wires of the wiring layer of the second active layer 210 through the second lower pad 230d. The first connection terminal 300 may also be connected to the first through electrode 120 through the first upper pad 130u.

The first connection terminal 300 may include solder. In some example embodiments, the first connection terminal 300 may include a pillar and solder. The solder may include tin (Sn), indium (In), bismuth (Bi), antimony (Sb), copper (Cu), silver (Ag), zinc (Zn), and/or an alloy thereof. For example, the solder may include Sn, Sn—Ag, Sn—Au, Sn—Cu, Sn—Bi, Sn—Zn, Sn—Ag—Cu, Sn—Ag—Bi, Sn—Ag—Zn, Sn—Cu—Bi, Sn—Cu—Zn, Sn—Bi—Zn, and/or the like. In some example embodiments, the solder may be referred to as a bump or a solder bump.

When the first connection terminal 300 includes a pillar and solder, the solder may be arranged on the pillar. For example, the pillar may include nickel (Ni), copper (Cu), palladium (Pd), platinum (Pt), gold (Au), or a combination thereof. In some example embodiments, the pillar may function as a pad and include Cu. Accordingly, the pillar may be referred to as a bump pad, a Cu pad, or a Cu pillar. When the pillar functions as a pad, a separate pad may not be formed on the bottom surface of the first memory chip 200-1.

When the first memory chip 200-1 is stacked on the base chip 100 through the first connection terminal 300, an adhesive layer 350 may be between the base chip 100 and the first memory chip 200-1. For example, the adhesive layer 350 may fill between the base chip 100 and the first memory chip 200-1 and cover the side surface of the first connection terminal 300. As shown in FIGS. 1A and 1B, the adhesive layer 350 may protrude from the side surfaces of the base chip 100 and the inner sealant 400 to cover a portion of the side surface of the base chip 100 and a portion of the side surface of the inner sealant 400. For example, the adhesive layer 350 may include a non-conductive film (NCF). An NCF may be used as an adhesive layer when a semiconductor chip is bonded in a thermal compression bonding (TCB) manner in a semiconductor chip stacking process. However, in the semiconductor package 1000 of some example embodiments, the material of the adhesive layer 350 is not limited to an NCF. In some example embodiments, instead of the adhesive layer 350, an underfill may fill between the base chip 100 and the first memory chip 200-1.

In the first semiconductor device 1100 of the semiconductor package 1000 of some example embodiments, except for the first memory chip 200-1 among the memory chips 200, each of the memory chips 200 above the first memory chip 200-1 may be stacked, through HCB, on a memory chip 200 directly therebelow. For example, in the case of two adjacent memory chips 200, the second upper pad 230u and the second upper protective layer 240u at the top of the lower memory chip 200 may be respectively bonded to the second lower pad 230d and the second lower protective layer 240d at the bottom of the upper memory chip 200 so that HCB may be formed.

The inner sealant 400 may seal the memory chips 200 above the base chip 100. For example, the inner sealant 400 may surround the side surfaces of the memory chips 200 on the adhesive layer 350 and seal the memory chips 200. As shown in FIGS. 1A and 1B, the inner sealant 400 may not cover the top surface of the topmost memory chip 200, e.g., the twelfth memory chip 200-12. Accordingly, the top surface of the twelfth memory chip 200-12 may be exposed by the inner sealant 400. The top surface of the inner sealant 400 may be coplanar or substantially coplanar with the top surface of the twelfth memory chip 200-12. However, in some example embodiments, the inner sealant 400 may cover the top surface of the topmost memory chip 200, e.g., the twelfth memory chip 200-12.

The inner sealant 400 may include an insulating material, for example, thermosetting resin such as epoxy resin, thermoplastic resin such as polyimide, or resin including a reinforcing material such as an inorganic filler. For example, the inner sealant 400 may include an Ajinomoto build-up film (ABF), flame retardant 4 (FR-4), or bismaleimide triazine (BT). The inner sealant 400 may include a molding material, such as an epoxy mold compound (EMC), or a photosensitive material, such as a photo-imageable encapsulant (PIE). However, the material of the inner sealant 400 is not limited to those mentioned above.

Hereinafter, for convenience of description, the memory chips 200 and the inner sealant 400 are collectively referred to as a chip stack structure CSS, which is used to distinguish the memory chips 200 and the inner sealant 400 from the base chip 100. For example, the first semiconductor device 1100 may include the base chip 100 and the chip stack structure CSS. The chip stack structure CSS may be stacked on the base chip 100 through the first connection terminal 300 and the adhesive layer 350.

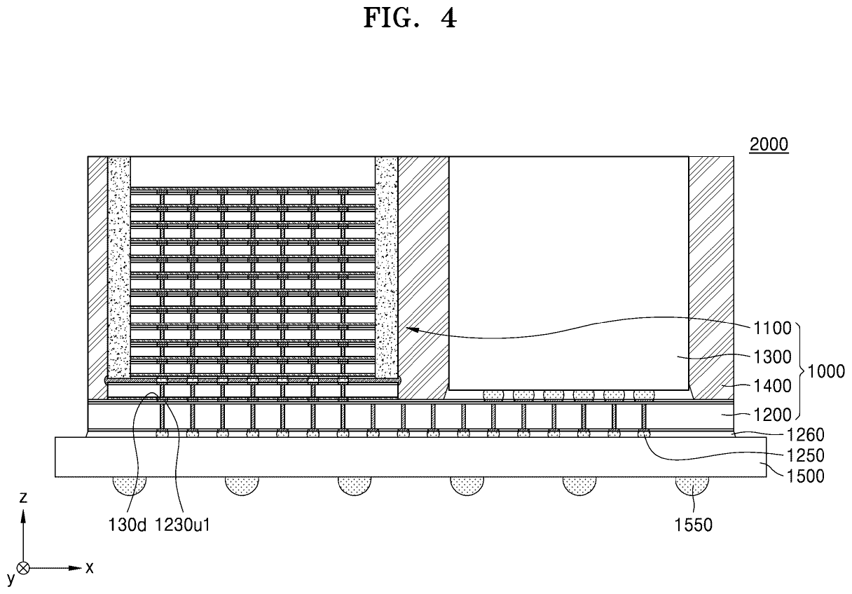

The interposer 1200 may mediate signal transmission between the first semiconductor device 1100 and the second semiconductor device 1300. For example, the first semiconductor device 1100 and the second semiconductor device 1300 may be mounted on the interposer 1200 and connected to each other by the interposer 1200. The interposer 1200 may mediate transmission of signals, power, or the like between the first semiconductor device 1100 and a package substrate 1500 (in FIG. 4) and between the second semiconductor device 1300 and the package substrate 1500. For example, the interposer 1200 may be mounted on the package substrate 1500 and may connect the first semiconductor device 1100 and the second semiconductor device 1300, which are on the top surface of the interposer 1200, to the package substrate 1500.

In the semiconductor package 1000 of some example embodiments, the interposer 1200 may be used to convert or transmit an electrical signal between the first semiconductor device 1100 and the second semiconductor device 1300. Accordingly, active devices may not be included in the interposer 1200. However, in some example embodiments, the interposer 1200 may include devices that control signal transmission.

The interposer 1200 may include a body layer 1201, a wiring layer 1210, a through electrode 1220, an interposer pad 1230, a protective layer 1240, and a first external connection terminal 1250. For example, the body layer 1201 may include silicon (Si). Accordingly, the interposer 1200 may correspond to a Si interposer. However, the interposer 1200 is not limited to the Si interposer.

The wiring layer 1210 may be arranged on the body layer 1201 and may include an interlayer insulating layer and wires. The wires may connect the first semiconductor device 1100 to the second semiconductor device 1300. The wires may also connect the through electrode 1220 to the interposer pad 1230 at the top of the interposer 1200.

The through electrode 1220 may extend through the body layer 1201. Because the body layer 1201 includes Si, the through electrode 1220 may correspond to a TSV. The through electrode 1220 may extend into the wiring layer 1210 and may be connected to wires of the wiring layer 1210. The through electrode 1220 may also be connected to the first external connection terminal 1250 through the interposer pad 1230 at the bottom of the interposer 1200. The structure of the through electrode 1220 may be the same as that of the first through electrode 120 of the base chip 100 of the first semiconductor device 1100.

The interposer pad 1230 may include interposer upper pads (e.g., 1230u1 and 1230u2) and an interposer lower pad 1230d. The interposer upper pads (1230u1 and 1230u2) may be arranged on the top surface of the wiring layer 1210. The interposer upper pads (1230u1 and 1230u2) may be connected to wires of the wiring layer 1210. The interposer upper pads (1230u1 and 1230u2) may be connected to the through electrode 1220 through wires of the wiring layer 1210.

The interposer upper pads (1230u1 and 1230u2) may include a first interposer upper pad 1230u1 connected to the first semiconductor device 1100 and a second interposer upper pad 1230u2 connected to the second semiconductor device 1300. The first interposer upper pad 1230u1 may be connected to the first lower pad 130d of the base chip 100 of the first semiconductor device 1100 through HCB. The second interposer upper pad 1230u2 may be connected to a second external connection terminal 1350 of the second semiconductor device 1300. Accordingly, the size and pitch of the first interposer upper pad 1230u1 may be less than those of the second interposer upper pad 1230u2. However, in some example embodiments, the first interposer upper pad 1230u1 and the second interposer upper pad 1230u2 may have the same or substantially the same size and pitch.

The interposer lower pad 1230d may be arranged on the bottom surface of the body layer 1201. The first external connection terminal 1250 may be arranged on the interposer lower pad 1230d. Accordingly, the first external connection terminal 1250 may be connected to wires of the wiring layer 1210 through the interposer lower pad 1230d and the through electrode 1220.

For example, the interposer pad 1230 may include at least one selected from the group consisting of aluminum (Al), copper (Cu), nickel (Ni), tungsten (W), platinum (Pt), and gold (Au). In the semiconductor package 1000 of some example embodiments, the interposer pad 1230 may include Cu. However, the material of the interposer pad 1230 is not limited to Cu.

The protective layer 1240 may be arranged in the bottom and top of the interposer 1200. For example, the protective layer 1240 may include an upper protective layer 1240u and a lower protective layer 1240d. The upper protective layer 1240u may be arranged on the top surface of the wiring layer 1210 Each of the interposer upper pads (1230u1 and 1230u2 ) may pass through at least a portion of the upper protective layer 1240u. For example, each of the interposer upper pads (1230u1 and 1230u2 ) may pass through at least a portion of the upper protective layer 1240u to be connected to wires of the wiring layer 1210.

The lower protective layer 1240d may be arranged on the bottom surface of the body layer 1201. The interposer lower pad 1230d may pass through at least a portion of the lower protective layer 1240d. For example, the interposer lower pad 1230d may pass through at least a portion of the lower protective layer 1240d to be connected to the through electrode 1220.

For example, the protective layer 1240 may include an oxide film, a nitride film, a carbide film, a polymer, or a combination thereof. However, the material of the protective layer 1240 is not limited thereto. The protective layer 1240 may have a single-film or multi-film structure.

The first external connection terminal 1250 may be arranged on the interposer pad 1230, e.g., the interposer lower pad 1230d, at the bottom of the interposer 1200. The first external connection terminal 1250 may be connected to the through electrode 1220 through the interposer lower pad 1230d. The first external connection terminal 1250 may include solder. In some example embodiments, the first external connection terminal 1250 may include a pillar and solder. The description of the first external connection terminal 1250 may be the same as that of the first connection terminal 300 of the first semiconductor device 1100.

In the semiconductor package 1000 of some example embodiments, the interposer 1200 may correspond to a 2.5-dimensional (2.5D) interposer. However, the interposer 1200 is not limited to the 2.5D interposer. For example, the interposer 1200 may correspond to a 2.3D interposer. An interposer may include a 2.5D interposer and a 2.3D interposer. In some example embodiments, an interposer structure may be subdivided by including an Si bridge. Accordingly, a structure except for a 2.5D interposer may be referred to as a 2.xD interposer.

A 2.5D interposer may refer to an Si interposer and may include a TSV therein. A 2.3D interposer may refer to an organic or inorganic interposer. In the case of an organic interposer, polyimide, benzocyclobutene (BCB), or polybenzoxazole (PBO) may be used as a body layer. In the case of an inorganic interposer, ceramic or glass may be used as a body layer. When the 2.3D interposer includes a through electrode, the through electrode may be referred to as a through dielectric via (TDV) or a through glass via (TGV) according to the material of the body layer. In some example embodiments, the 2.3D interposer may be referred to as a panel level package (PLP) interposer or a re-distribution layer (RDL) interposer.

The second semiconductor device 1300 may be mounted on the interposer 1200 through the second external connection terminal 1350. As seen in FIG. 1A, the second semiconductor device 1300 may be adjacent to the first semiconductor device 1100 and arranged on the right portion of the interposer 1200 in the x-direction. However, the position of the second semiconductor device 1300 is not limited thereto. For example, the first semiconductor device 1100 may be arranged on the right portion of the interposer 1200 in the x-direction, and the second semiconductor device 1300 may be arranged on the left portion of the interposer 1200 in the x-direction.

The second semiconductor device 1300 may include a chip or package structure. In the semiconductor package 1000 of some example embodiments, the second semiconductor device 1300 may have a chip structure. For example, the second semiconductor device 1300 may include a logic chip. Accordingly, the second semiconductor device 1300 may include a plurality of logic devices therein. The logic devices have been described in the above description of the first semiconductor device 1100.

The second semiconductor device 1300 may be referred to as a central processing unit (CPU) chip, a microprocessor unit (MPU) chip, a graphics processing unit (GPU) chip, a neural processing unit (NPU) chip, a system-on-glass (SOG) chip, an application specific integrated circuit (ASIC) chip, an application processor (AP) chip, or a control chip, according to the function thereof.

In the semiconductor package 1000 of some example embodiments, the second semiconductor device 1300 may have a chip structure and a system-on-chip (SoC) structure or a chiplet structure. In an SoC structure, multiple systems are integrated into a single chip. Accordingly, the second semiconductor device 1300 having an SoC structure may perform a computational function, data storage, analog-digital conversion, and the like in a single chip. In a chiplet structure, a logic chip is divided into separate chips by functions and the separate chips are connected to each other. The second semiconductor device 1300 having a chiplet structure may overcome the performance limitation of a single chip.

The second semiconductor device 1300 may also include devices that support communication. However, in some example embodiments, the devices that support communication may be provided in a separate chip, e.g., a modem chip, and the separate chip may be arranged on the interposer 1200 in a structure coupled to the second semiconductor device 1300.

An underfill 1360 may fill between the second semiconductor device 1300 and the interposer 1200. The underfill 1360 may cover the side surface of the second external connection terminal 1350. The underfill 1360 may protrude from the side surface of the second semiconductor device 1300 and cover a portion of the side surface of the second semiconductor device 1300. In some example embodiments, the underfill 1360 may be replaced by an adhesive layer and/or an adhesive film.

The outer sealant 1400 may be arranged on the interposer 1200 to cover and seal the first semiconductor device 1100 and the second semiconductor device 1300. As shown in FIG. 1A, the outer sealant 1400 may not cover the top surfaces of the first semiconductor device 1100 and the second semiconductor device 1300. For example, the top surface of the outer sealant 1400 may be coplanar or substantially coplanar with the top surfaces of the first semiconductor device 1100 and the second semiconductor device 1300. This structure may be attributed to a back grinding process for the outer sealant 1400. However, in some example embodiments, the top surface of at least one of the first semiconductor device 1100 and the second semiconductor device 1300, e.g., the first semiconductor device 1100, may be covered by the outer sealant 1400.

The material of the outer sealant 1400 has been described in the description of the inner sealant 400 of the first semiconductor device 1100. However, the outer sealant 1400 may include a material that is the same as or different from the material of the inner sealant 400. Even when the outer sealant 1400 includes the same material as the inner sealant 400, the outer sealant 1400 may have different physical properties than the inner sealant 400 by adjusting the material composition and the filler amount of the outer sealant 1400. For example, the outer sealant 1400 and the inner sealant 400 may have different hardness or different coefficients of thermal expansion.

The semiconductor package 1000 of some example embodiments may have a chip-type package structure in which the first semiconductor device 1100 and the second semiconductor device 1300 are arranged on the interposer 1200 and sealed by the outer sealant 1400. This chip-type package may be referred to as a molded interposer chip or a chip package.

In the semiconductor package 1000 of some example embodiments, the first semiconductor device 1100 may have a structure in which the base chip 100 is connected to the interposer 1200 through HCB. Accordingly, the semiconductor package 1000 of some example embodiments may easily implement high bandwidth, high speed, and wide input/output (I/O) in a structure, e.g., an HBM package structure, in which memory chips 200 are stacked on the base chip 100. Furthermore, as described in a method of manufacturing the semiconductor package 1000 below, the base chip 100 may be stacked on the interposer 1200 after being manufactured and tested separately from the chip stack structure CSS including the memory chips 200 so that cost and time may be reduced and the yield of semiconductor packages may be increased. For example, because the base chip 100 and the chip stack structure CSS are independently manufactured and tested, freedom may be increased in terms of space and time of manufacturing processes. In addition, because a process quality guarantee region is clarified with respect to each of the chip stack structure CSS and the base chip 100, the separation of the stack yield may be possible, thereby increasing the yield of semiconductor packages.

A 2.5D package structure recently used for high performance computing (HPC) enables high-speed communication between a logic chip and a memory chip through an interposer. With the current trend in HPC toward parallel computing, high-speed communication with multiple memories is increasingly important. Accordingly, the number of channels in an HBM package is increasing, thereby increasing a bandwidth. To continuously increase the bandwidth, it is necessary to increase the area of the physical layer (PHY) between a logic chip and an HBM package and decrease the pitch of a connection terminal. However, in the case of interposers according to the related art, although the pitch of connection pads may be miniaturized through a back-end-of-line (BEOL) process, there is a limit to the scaling of the PHY because logic chips and HBM packages, and especially the HBM packages are mounted on an interposer through connection terminals such as bumps. However, in the case of the semiconductor package 1000 of some example embodiments, the pitch of a connection pad may be significantly reduced as the first semiconductor device 1100 is mounted on the interposer 1200 through HCB so that the problems described above may be solved.

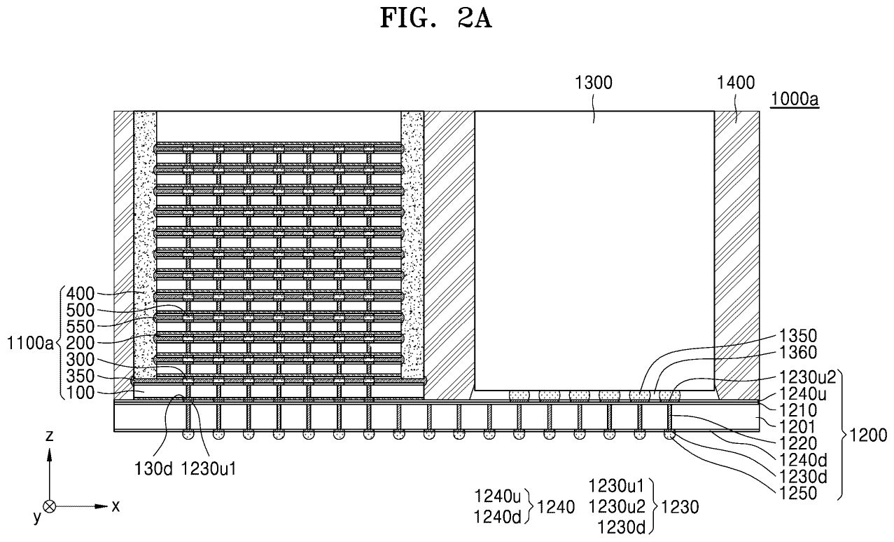

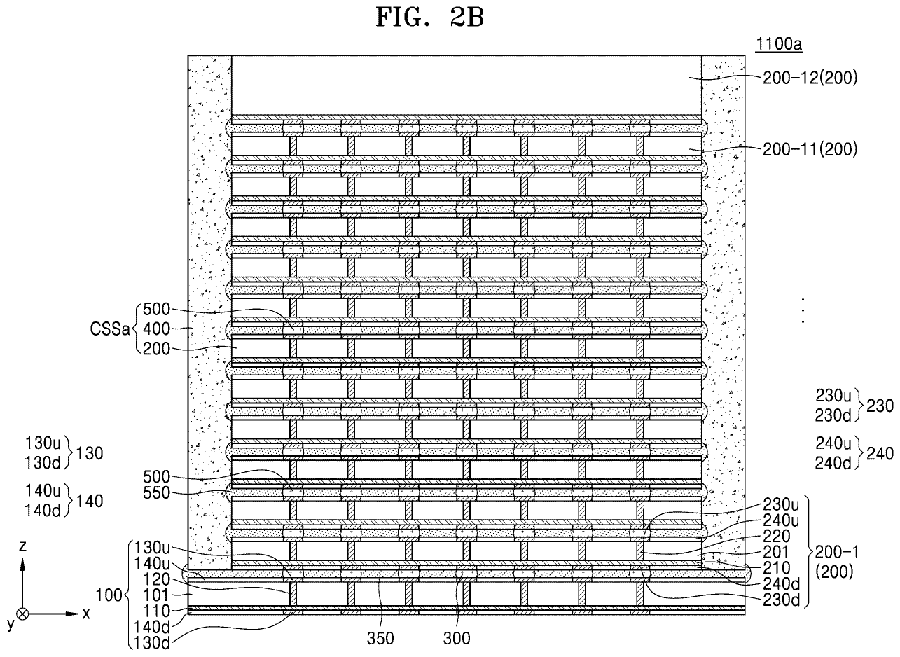

FIGS. 2A and 2B are cross-sectional views of a semiconductor package according to an embodiment. FIG. 2B shows in detail a first semiconductor device of the semiconductor package of FIG. 2A. Redundant descriptions already given with reference to FIGS. 1A and 1B will be brief or omitted.

Referring to FIGS. 2A and 2B, a semiconductor package 1000a may be different from the semiconductor package 1000 of FIG. 1 in the structure of a first semiconductor device 1100a. Specifically, the semiconductor package 1000a of some example embodiments may include the first semiconductor device 1100a, the interposer 1200, the second semiconductor device 1300, and the outer sealant 1400. The interposer 1200, the second semiconductor device 1300, and the outer sealant 1400 have been described in the description of the semiconductor package 1000 of FIG. 1A.

In the semiconductor package 1000a of some example embodiments, the first semiconductor device 1100a may include an HBM package. The first semiconductor device 1100a may include the base chip 100, the memory chips 200, the first connection terminal 300, the inner sealant 400, and a second connection terminal 500. The base chip 100, the memory chips 200, the first connection terminal 300, and the inner sealant 400 have been described in the description of the first semiconductor device 1100 of the semiconductor package 1000 of FIG. 1A.

In the first semiconductor device 1100a of the semiconductor package 1000a of some example embodiments, a chip stack structure CSSa may be different from the chip stack structure CSS of the first semiconductor device 1100 of the semiconductor package 1000 of FIG. 1A. Specifically, the chip stack structure CSSa of the first semiconductor device 1100a may include the memory chips 200, the inner sealant 400, and the second connection terminal 500. In the chip stack structure CSSa, the memory chips 200 may be stacked through the second connection terminal 500. For example, the second connection terminal 500 may be between the second upper pad 230u of a lower memory chip 200 among two adjacent memory chips 200 and a second lower pad 230d of an upper memory chip 200 among the two adjacent memory chips 200. The structure or material of the second connection terminal 500 may be the same as that of the first connection terminal 300 of the first semiconductor device 1100 of the semiconductor package 1000 of FIG. 1A.

As the memory chips 200 are stacked through the second connection terminal 500 in the chip stack structure CSSa of the first semiconductor device 1100a, an adhesive layer 550 may be provided between two adjacent memory chips 200. For example, the adhesive layer 550 may fill between two adjacent memory chips 200 and cover the side surface of the second connection terminal 500. As shown in FIGS. 2A and 2B, the adhesive layer 550 may protrude from the side surfaces of the memory chips 200 and cover the side surfaces of the memory chips 200. In some example embodiments, the adhesive layer 550 may protrude from the side surfaces of the memory chips 200 and cover at least half of the side surface of each of the memory chips 200. In this case, one adhesive layer 550 in an upper portion of each of the memory chips 200 may be in contact with another adhesive layer 550 in a lower portion of each memory chip 200 on the side surface of the memory chip 200. For example, the adhesive layer 550 may include an NCF. However, the material of the adhesive layer 550 is not limited to an NCF. In some example embodiments, the adhesive layer 550 may be replaced by an underfill.

The inner sealant 400 of the chip stack structure CSSa may cover the side surfaces of the memory chips 200 and the side surface of the adhesive layer 550. In the first semiconductor device 1100a of the semiconductor package 1000a of some example embodiments, the chip stack structure CSSa may be stacked on the base chip 100 through the first connection terminal 300 and the adhesive layer 350.

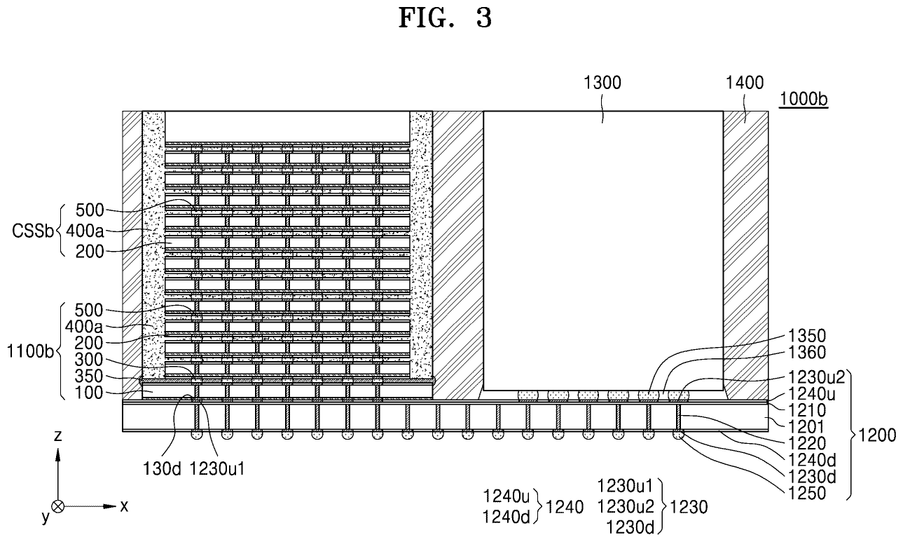

FIG. 3 is a cross-sectional view of a semiconductor package according to an embodiment. Redundant descriptions already given with reference to FIGS. 1A to 2B will be brief or omitted.

Referring to FIG. 3, a semiconductor package 1000b of some example embodiments may be different from the semiconductor package 1000 of FIG. 1A in the structure of a first semiconductor device 1100b. Specifically, the semiconductor package 1000b of some example embodiments may include the first semiconductor device 1100b, the interposer 1200, the second semiconductor device 1300, and the outer sealant 1400. The interposer 1200, the second semiconductor device 1300, and the outer sealant 1400 have been described in the description of the semiconductor package 1000 of FIG. 1A.

In the semiconductor package 1000b of some example embodiments, the first semiconductor device 1100b may include an HBM package. The first semiconductor device 1100b may include the base chip 100, the memory chips 200, the first connection terminal 300, an inner sealant 400a, and the second connection terminal 500. The base chip 100, the memory chips 200, the first connection terminal 300, and the second connection terminal 500 have been described in the description of the first semiconductor device 1100a of the semiconductor package 1000a of FIG. 2A.

In the first semiconductor device 1100b of the semiconductor package 1000b of some example embodiments, a chip stack structure CSSb may be different from the chip stack structure CSSa of the first semiconductor device 1100a of the semiconductor package 1000a of FIG. 2A. Specifically, the chip stack structure CSSb of the first semiconductor device 1100b may include the memory chips 200, the inner sealant 400a, and the second connection terminal 500. In the chip stack structure CSSb, the memory chips 200 may be stacked through the second connection terminal 500.

The memory chips 200 may be stacked through the second connection terminal 500 in the chip stack structure CSSb of the first semiconductor device 1100b, and the inner sealant 400a may fill between two adjacent memory chips 200. For example, the inner sealant 400a may cover the side surfaces of the memory chips 200 and fill a space between two adjacent memory chips 200. The chip stack structure CSSb of the first semiconductor device 1100b may be attributed to the inner sealant 400a that is formed by a molded underfill (MUF) process.

FIG. 4 is a cross-sectional view of a system package according to an embodiment. FIGS. 1A and 1B are also referred to, and redundant descriptions already given with reference to FIGS. 1A to 3 will be brief or omitted.

Referring to FIG. 4, a system package 2000 may include the semiconductor package 1000 and the package substrate 1500. In the system package 2000 of some example embodiments, the semiconductor package 1000 may correspond to the semiconductor package 1000 of FIG. 1A. Accordingly, the semiconductor package 1000 may include the first semiconductor device 1100, the interposer 1200, the second semiconductor device 1300, and the outer sealant 1400. However, in the system package 2000 of some example embodiments, the semiconductor package 1000 is not limited to the semiconductor package 1000 of FIG. 1A. For example, instead of the semiconductor package 1000 of FIG. 1A, the semiconductor package 1000a of FIG. 2A or the semiconductor package 1000b of FIG. 3 may be applied to the system package 2000.

In the system package 2000 of some example embodiments, the package substrate 1500 may function as a support substrate, and the semiconductor package 1000 may be mounted on the package substrate 1500. The package substrate 1500 may include at least one layer of a wiring line therein. When there are multiple layers of wiring lines, wiring lines in different layers may be connected to each other through a via. For example, the package substrate 1500 may be formed based on a ceramic substrate, a printed circuit board (PCB), a glass substrate, and/or an interposer substrate. A third external connection terminal 1550 may be arranged on the bottom surface of the package substrate 1500. The system package 2000 of some example embodiments may be stacked on an external system substrate or a main board through the third external connection terminal 1550.

The semiconductor package 1000 may be mounted on the package substrate 1500 through the first external connection terminal 1250 of the interposer 1200. Semiconductor devices (e.g., 1100 and 1300) may be mounted on the package substrate 1500 via the interposer 1200. The interposer 1200 may connect the semiconductor devices (1100 and 1300) to each other. The interposer 1200 may also connect the semiconductor devices (1100 and 1300) to the package substrate 1500. An underfill 1260 may fill between the interposer 1200 and the package substrate 1500 and between first external connection terminals 1250. In some example embodiments, the underfill 1260 may be replaced by an adhesive layer and/or an adhesive film.

The structure of the system package 2000 of some example embodiments may be referred to as a 2.5D package structure. The 2.5D package structure may be a comparative concept to a 3D package structure in which all semiconductor chips are stacked together and there is no interposer. Both the 2.5D package structure and the 3D package structure may be included in a system-in-package (SIP) structure. The system package 2000 of some example embodiments may also belong to a semiconductor package, but the term “system package” is used to be distinguished from the semiconductor package 1000 that is a component. The same concept may be applied to other system packages described below.

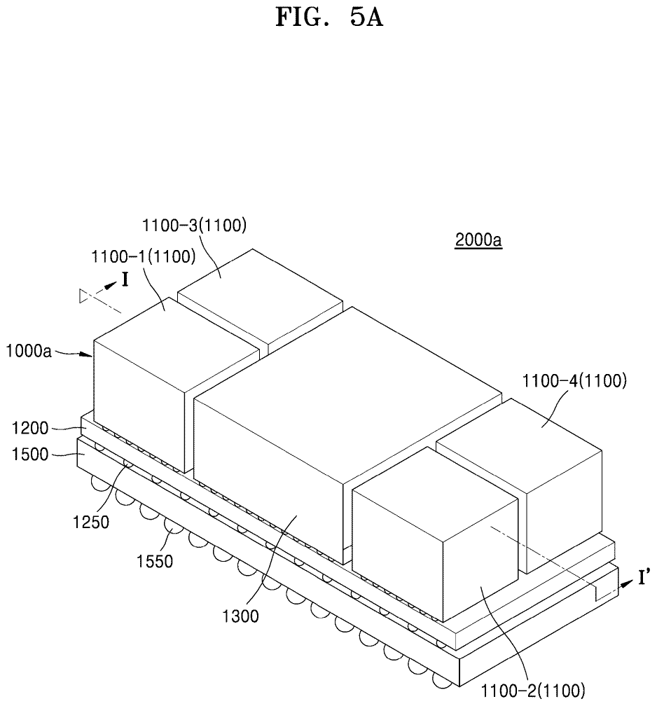

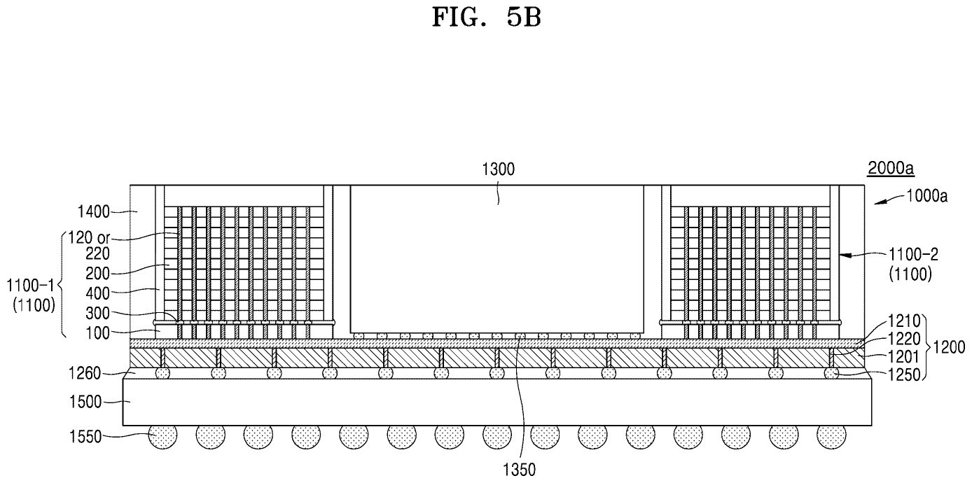

FIGS. 5A and 5B are respectively a perspective view and a cross-sectional view of a system package according to an embodiment. FIG. 5B may be a cross-sectional view taken along line I-I′ in FIG. 5A. FIGS. 1A and 1B are also referred to, and redundant descriptions already given with reference to FIGS. 1A to 4 will be brief or omitted.

Referring to FIGS. 5A and 5B, a system package 2000a of some example embodiments may be different from the system package 2000 of FIG. 4 in that the semiconductor package 1000a includes four first semiconductor devices 1100. Specifically, the system package 2000a of some example embodiments may include the semiconductor package 1000a and the package substrate 1500. The package substrate 1500 has been described in the description of the system package 2000 of FIG. 4.

In the system package 2000a of some example embodiments, the semiconductor package 1000a may include the first semiconductor devices 1100, the interposer 1200, the second semiconductor device 1300, and the outer sealant 1400. The interposer 1200, the second semiconductor device 1300, and the outer sealant 1400 have been described in the description of the semiconductor package 1000 of FIG. 1A.

In the system package 2000a of some example embodiments, the semiconductor package 1000a may include four first semiconductor devices 1100, as shown in FIG. 5A. Each of the four first semiconductor devices 1100 may be connected to the interposer 1200 through HCB. The four first semiconductor devices 1100 may be arranged on the interposer 1200 such that two first semiconductor devices 1100 of the four first semiconductor devices 1100 are on opposite sides of the second semiconductor device 1300. For example, a lower left first semiconductor device 1100-1 and an upper left first semiconductor device 1100-3 may be arranged on the left of the second semiconductor device 1300, and a lower right first semiconductor device 1100-2 and an upper right first semiconductor device 1100-4 may be arranged on the right of the second semiconductor device 1300. However, in the system package 2000a of some example embodiments, the number of first semiconductor devices 1100 is not limited to 4. For example, one to three first semiconductor devices 1100 or at least five first semiconductor devices 1100 may be arranged on the interposer 1200.

For example, each of the first semiconductor devices 1100 may correspond to the first semiconductor device 1100 of the semiconductor package 1000 of FIG. 1A. Accordingly, each first semiconductor device 1100 may include the base chip 100, the memory chips 200, the first connection terminal 300, and the inner sealant 400. The base chip 100 may be stacked on the interposer 1200 through HCB. The memory chips 200 and the inner sealant 400 may form the chip stack structure CSS and may be stacked on the base chip 100 through the first connection terminal 300 and the adhesive layer 350. However, the first semiconductor device 1100 is not limited to the first semiconductor device 1100 of the semiconductor package 1000 of FIG. 1A. For example, instead of the first semiconductor device 1100 of the semiconductor package 1000 of FIG. 1A, the first semiconductor device 1100a of the semiconductor package 1000a of FIG. 2A or the first semiconductor device 1100b of the semiconductor package 1000b of FIG. 3 may be applied to the semiconductor package 1000a of the system package 2000a.

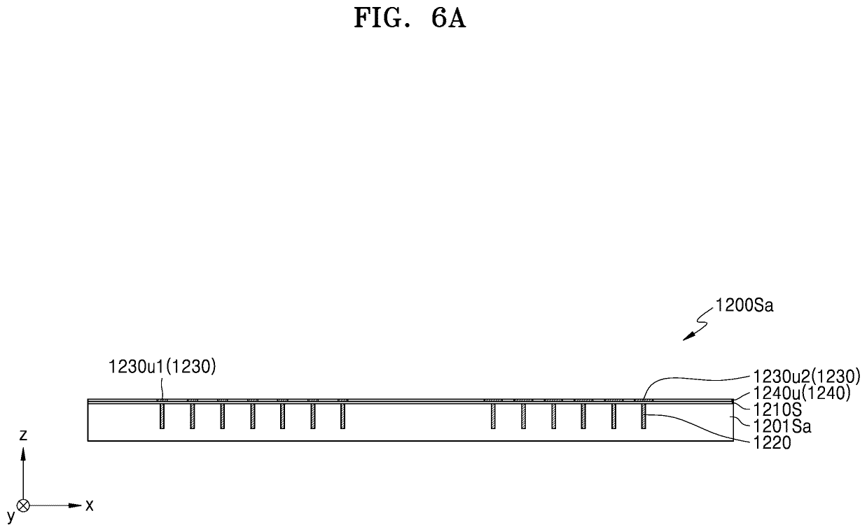

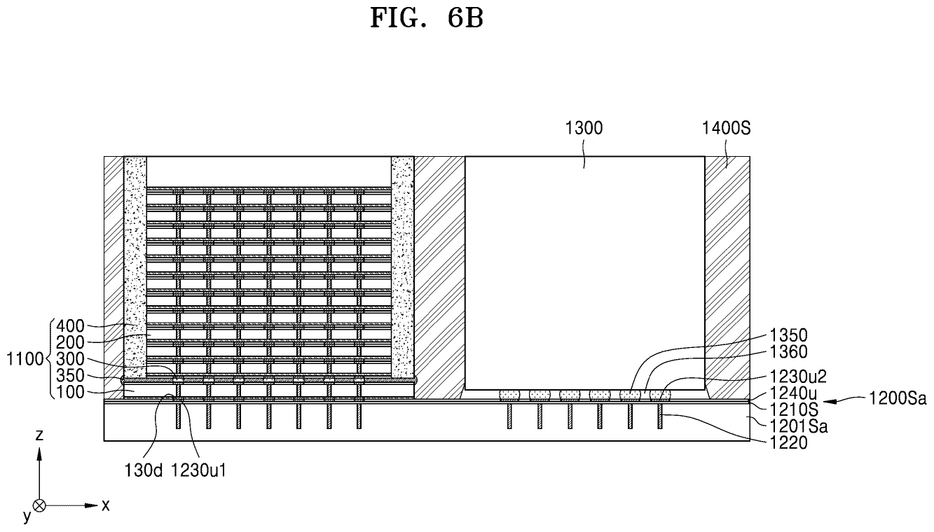

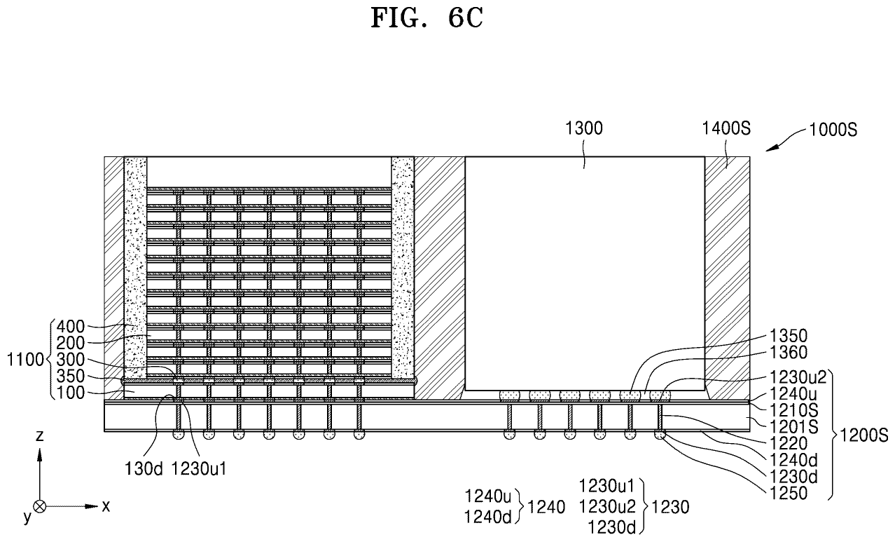

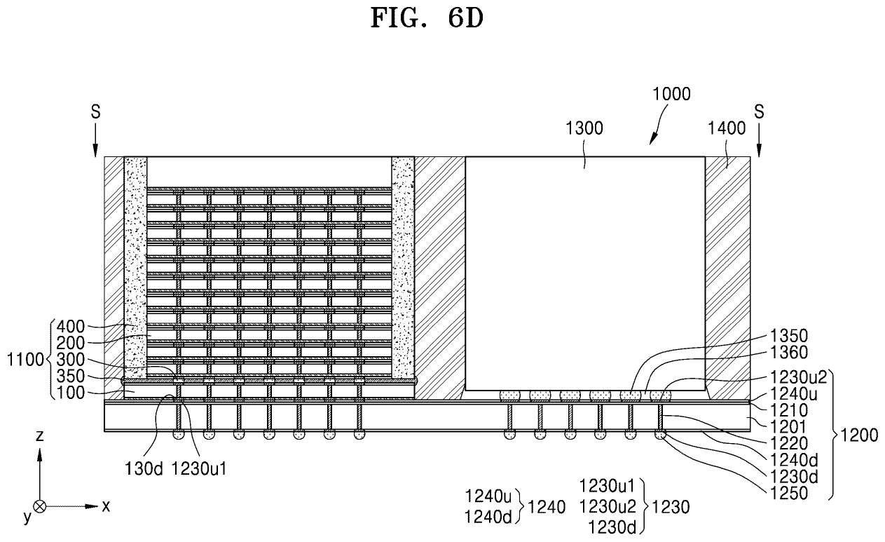

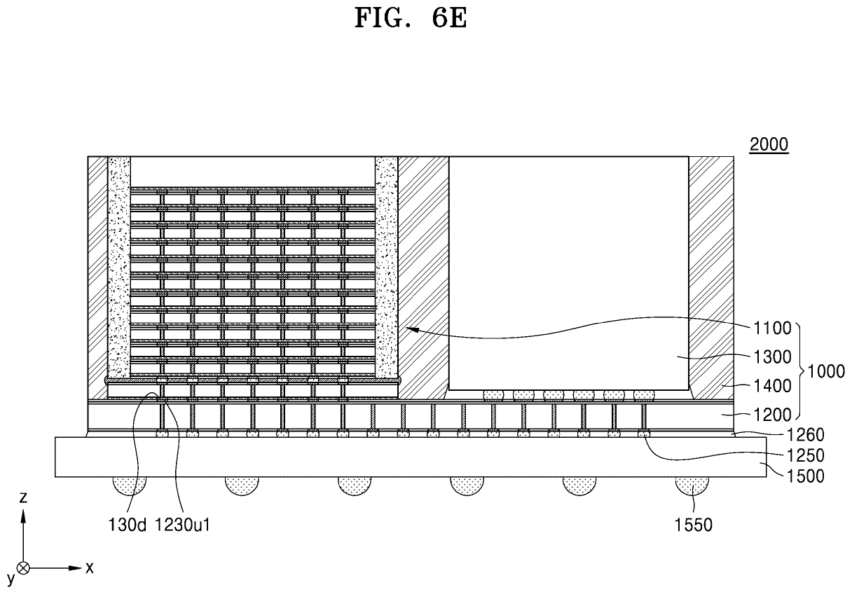

FIGS. 6A to 6E are schematic cross-sectional views of stages in a method of manufacturing a system package, according to an embodiment. FIGS. 1A, 1B, and 4 are also referred to, and redundant descriptions already given with reference to FIGS. 1A to 5B will be brief or omitted.

Referring to FIG. 6A, in the method of manufacturing a system package in some example embodiments, a through electrode 1220 may be formed in an initial body layer 1201Sa, and an interposer pad 1230 may be formed on an initial wiring layer 1210S on the initial body layer 1201Sa. An initial interposer substrate 1200Sa may be formed by forming the through electrode 1220 and the interposer pad 1230. The initial body layer 1201Sa and the initial wiring layer 1210S may each have a wafer-level size. Accordingly, the initial interposer substrate 1200Sa may also have a wafer-level size. The interposer pad 1230 may be formed in the protective layer 1240 (e.g., the upper protective layer 1240u) on the initial wiring layer 1210S. The interposer pad 1230 may include the first interposer upper pad 1230u1 and the second interposer upper pad 1230u2. The through electrode 1220, the first interposer upper pad 1230u1, and the second interposer upper pad 1230u2 have been described in the description of the interposer 1200 of the semiconductor package 1000 of FIG. 1A.

Referring to FIG. 6B, after the initial interposer substrate 1200Sa is formed, first semiconductor devices 1100 and second semiconductor devices 1300 may be mounted on the initial interposer substrate 1200Sa. An outer sealant 1400S may be formed to seal the first semiconductor devices 1100 and the second semiconductor devices 1300. The outer sealant 1400S may cover the side surface of each of the first semiconductor devices 1100 and the second semiconductor devices 1300, which are on the initial interposer substrate 1200Sa.

Each of the first semiconductor devices 1100 and each of the second semiconductor devices 1300 have been described in the descriptions of the first semiconductor device 1100 and the second semiconductor device 1300 of the semiconductor package 1000 of FIG. 1A. Accordingly, in each of the first semiconductor devices 1100, the base chip 100 may be connected to the initial interposer substrate 1200Sa through HCB, and the chip stack structure CSS may be stacked on the base chip 100 through the first connection terminal 300 and the adhesive layer 350. The chip stack structure CSS may include the memory chips 200 and the inner sealant 400, and the memory chips 200 may be stacked through HCB.

Instead of the first semiconductor devices 1100, first semiconductor devices 1100a of the semiconductor package 1000a of FIG. 2A or first semiconductor devices 1100b of the semiconductor package 1000b of FIG. 3 may be mounted on the initial interposer substrate 1200Sa. In this case, in each of the chip stack structures CSSa and CSSb, the memory chips 200 may be stacked through the second connection terminal 500, and the adhesive layer 550 or the inner sealant 400a may fill between the memory chips 200.

Referring to FIG. 6C, after the outer sealant 1400S is formed, a lower portion of the initial interposer substrate 1200Sa may be removed, and the interposer pad 1230 and the protective layer 1240 may be formed at the bottom. Thereafter, the first external connection terminal 1250 may be formed on the interposer pad 1230. An interposer substrate 1200S may be formed by forming the interposer pad 1230 and the first external connection terminal 1250. A semiconductor package structure 1000S may be formed by forming the interposer substrate 1200S. The interposer substrate 1200S may have a wafer-level size and may include a plurality of interposers 1200. Accordingly, the semiconductor package structure 1000S may include a plurality of semiconductor packages 1000. The interposer pad 1230 may include the interposer lower pad 1230d. The protective layer 1240 may include the lower protective layer 1240d.

Referring to FIG. 6D, after the semiconductor package structure 1000S is formed, the semiconductor package structure 1000S may be singulated into semiconductor packages 1000 by a sawing process S. For example, each of the semiconductor packages 1000 may correspond to the semiconductor package 1000 of FIG. 1A. The interposer substrate 1200S may also be singulated into interposers 1200.

The manufactured semiconductor package 1000 is not limited to the semiconductor package 1000 of FIG. 1A. For example, when the first semiconductor devices 1100a of the semiconductor package 1000a of FIG. 2A or the first semiconductor devices 1100b of the semiconductor package 1000b of FIG. 3 are mounted on the initial interposer substrate 1200Sa in FIG. 6B, the semiconductor package 1000a of FIG. 2A or the semiconductor package 1000b of FIG. 3 may be manufactured through singulation.

Referring to FIG. 6E, after the semiconductor package 1000 is manufactured, the system package 2000 may be manufactured by mounting the semiconductor package 1000 on the package substrate 1500. The semiconductor package 1000 may be mounted on the package substrate 1500 through the first external connection terminal 1250 and the underfill 1260. For example, the system package 2000 may correspond to the system package 2000 of FIG. 4.

FIGS. 7A to 7H are cross-sectional views of stages in a method of manufacturing a semiconductor package, according to an embodiment. FIGS. 7A to 7H show the stages of FIGS. 6B and 6C in detail. FIGS. 1A and 1B are also referred to, and redundant descriptions already given with reference to FIGS. 1A to 6E will be brief or omitted.

Referring to FIG. 7A, in the method of manufacturing a semiconductor package in some example embodiments, the base chip 100 of each of the first semiconductor devices 1100 may be stacked on the initial interposer substrate 1200Sa through HCB after the initial interposer substrate 1200Sa is formed in FIG. 6A. For example, the base chip 100 of each of the first semiconductor devices 1100 may be stacked on its corresponding portion of the initial interposer substrate 1200Sa through HCB. For convenience of description, only one first semiconductor device 1100 and only one second semiconductor device 1300 are described unless necessary.

The process of stacking the base chip 100 on the initial interposer substrate 1200Sa through HCB is specifically described below. An OH dangling bond may be formed on the upper protective layer 1240u of the initial interposer substrate 1200Sa and the lower protective layer 140d of the base chip 100 by performing a plasma treatment and ultrapure water cleaning on the initial interposer substrate 1200Sa and the base chip 100 before the initial interposer substrate 1200Sa and the base chip are bonded to each other. Thereafter, the base chip 100 may be bonded to the initial interposer substrate 1200Sa at room temperature such that the first lower pad 130d is aligned with the first interposer upper pad 1230u1. At the beginning of the bonding, OH dangling bonds between the upper protective layer 1240u of the initial interposer substrate 1200Sa and the lower protective layer 140d of the base chip 100 may form hydrogen bonding. Hydrogen bonding may have a relative low bonding force.

Thereafter, as heat may be applied through annealing, a solid bonding structure may be formed between the first interposer upper pad 1230u1 and the first lower pad 130d. Specifically, through annealing, metal expansion and metal diffusion may occur in the first interposer upper pad 1230u1 and the first lower pad 130d so that the first interposer upper pad 1230u1 and the first lower pad 130d may be integrated. Through annealing, hydrogen bonding between the upper protective layer 1240u of the initial interposer substrate 1200Sa and the lower protective layer 140d of the base chip 100 may change to oxide bonding. For example, to put this change simply in a chemical formula, it becomes —OH+→OH—->O+H₂O through high-temperature annealing. Oxide bonding may have a greater bonding force than hydrogen bonding. Consequently, the base chip 100 may be firmly bonded to the initial interposer substrate 1200Sa with a high bonding force through HCB.

Referring to FIG. 7B, after the stacking of the base chip 100, the chip stack structure CSS may be stacked on the base chip 100 through the first connection terminal 300 and the adhesive layer 350. The chip stack structure CSS may include the memory chips 200 and the inner sealant 400. The adhesive layer 350 may include a portion, which protrudes from the side surface of the base chip 100 and the side surface of the inner sealant 400. As the chip stack structure CSS is stacked on the base chip 100, the first semiconductor device 1100 may be mounted on the initial interposer substrate 1200Sa.

Referring to FIG. 7C, after the mounting of the first semiconductor device 1100, the second semiconductor device 1300 may be mounted on the initial interposer substrate 1200Sa. The second semiconductor device 1300 may be mounted on the initial interposer substrate 1200Sa through the second external connection terminal 1350 and the underfill 1360. The second external connection terminal 1350 may be connected to the second interposer upper pad 1230u2 of the initial interposer substrate 1200Sa.

Referring to FIG. 7D, after the mounting of the second semiconductor device 1300, an initial outer sealant 1400Sa may be formed on the initial interposer substrate 1200Sa to seal the first semiconductor device 1100 and the second semiconductor device 1300. The initial outer sealant 1400Sa may seal all the first semiconductor devices 1100 and the second semiconductor devices 1300 on the initial interposer substrate 1200Sa. As shown in FIG. 7D, the initial outer sealant 1400Sa may cover the top surfaces of the first semiconductor device 1100 and the second semiconductor device 1300.

Referring to FIG. 7E, an upper portion of the initial outer sealant 1400Sa may be removed by an external mold grinding process M/Ge. The outer sealant 1400S may be formed through the external mold grinding process M/Ge. The top surfaces of the first semiconductor device 1100 and the second semiconductor device 1300 may be exposed by the outer sealant 1400S.

Referring to FIG. 7F, the initial interposer substrate 1200Sa and the structures thereon may be turned over. As a result, the initial interposer substrate 1200Sa may be located above the first semiconductor device 1100 and the second semiconductor device 1300. In some example embodiments, a carrier substrate may be attached to the bottom surfaces of the first semiconductor device 1100, the second semiconductor device 1300, and the outer sealant 1400S by using an adhesive.

Referring to FIG. 7G, the through electrode 1220 may be exposed by removing a lower portion of the initial body layer 1201Sa by using a grinding process and an Si recess process. In detail, the lower portion of the initial body layer 1201Sa may be primarily removed by the grinding process. At this time, the through electrode 1220 may not exposed. Thereafter, the lower portion of the initial body layer 1201Sa may be additionally removed by the Si recess process such that the through electrode 1220 is exposed. For example, the Si recess process may be carried out through a dry etching process. However, in some example embodiments, a wet etching process may be used for the Si recess process.

The initial body layer 1201Sa may become a body layer 1201S through the grinding process and the Si recess process. In addition, the initial interposer substrate 1200Sa may become a thinner initial interposer substrate 1200Sb. After the Si recess process, the through electrode 1220 may slightly protrude from the bottom surface of the initial body layer 1201S. However, for convenience, it is illustrated in FIG. 7G that the through electrode 1220 does not protrude. Because the initial interposer substrate 1200Sb is turned over, the bottom surface of the initial body layer 1201S may face upward in FIG. 7G.

Referring to FIG. 7H, after the through electrode 1220 is exposed, the lower protective layer 1240d may be formed on the bottom surface of the body layer 1201S. Subsequently, the interposer pad, e.g., the interposer lower pad 1230d, may be formed in the lower protective layer 1240d. The interposer lower pad 1230d may pass through the lower protective layer 1240d and may be connected to the through electrode 1220. The interposer substrate 1200S may be formed by forming the interposer lower pad 1230d. Thereafter, the semiconductor package structure 1000S of FIG. 6C may be formed by forming the first external connection terminal 1250 on the interposer lower pad 1230d.

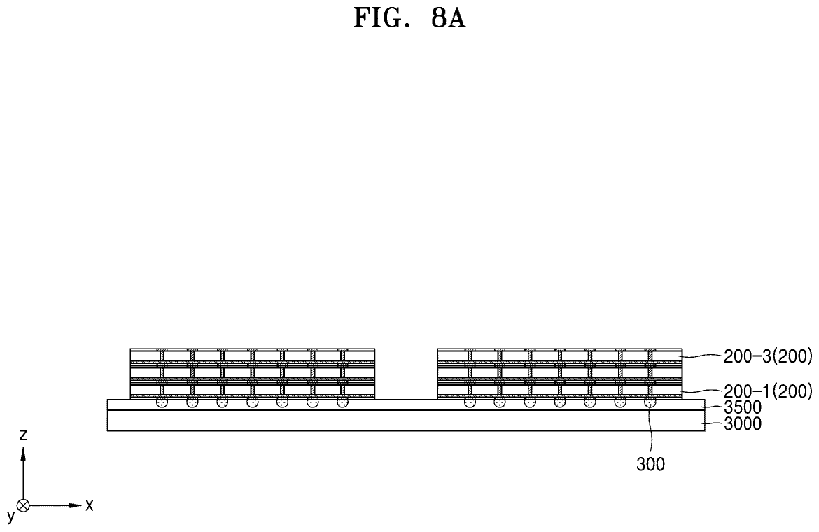

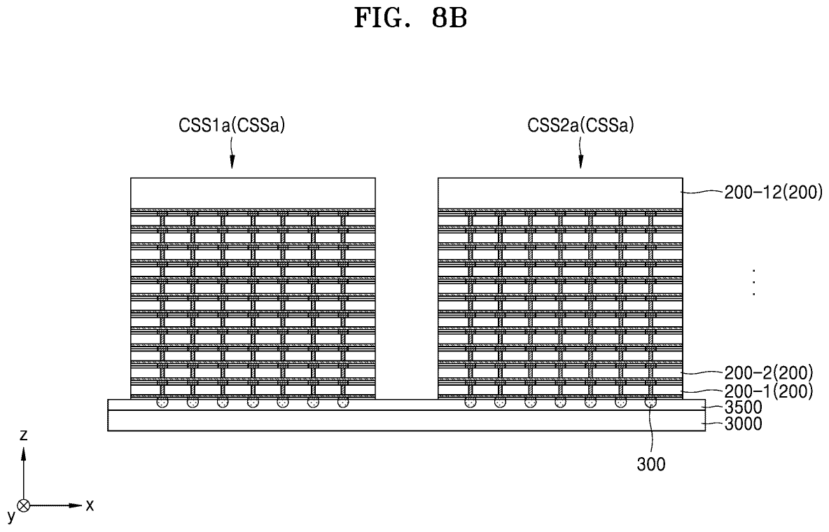

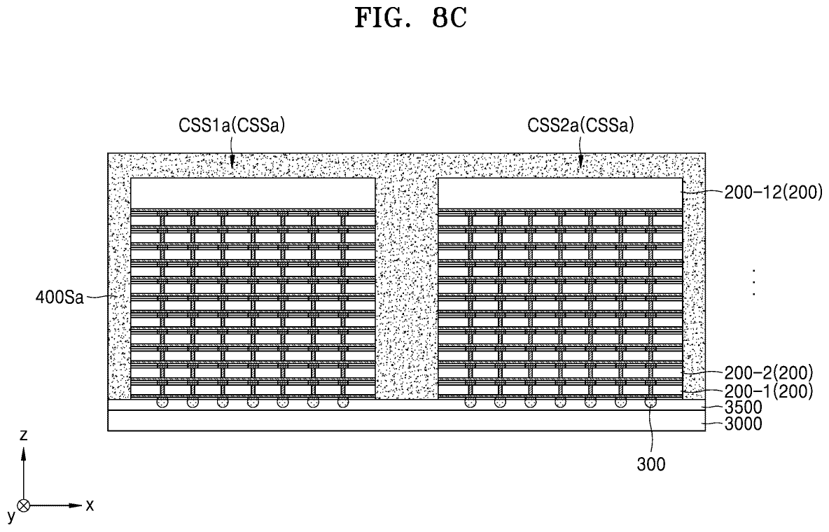

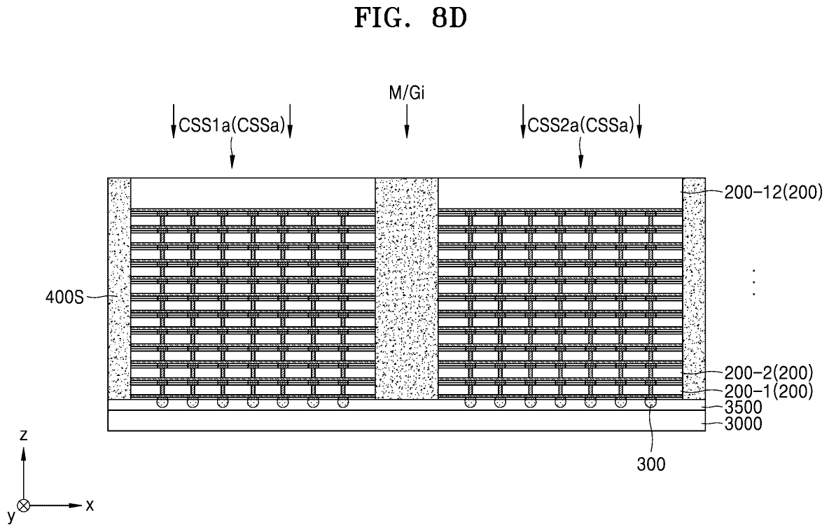

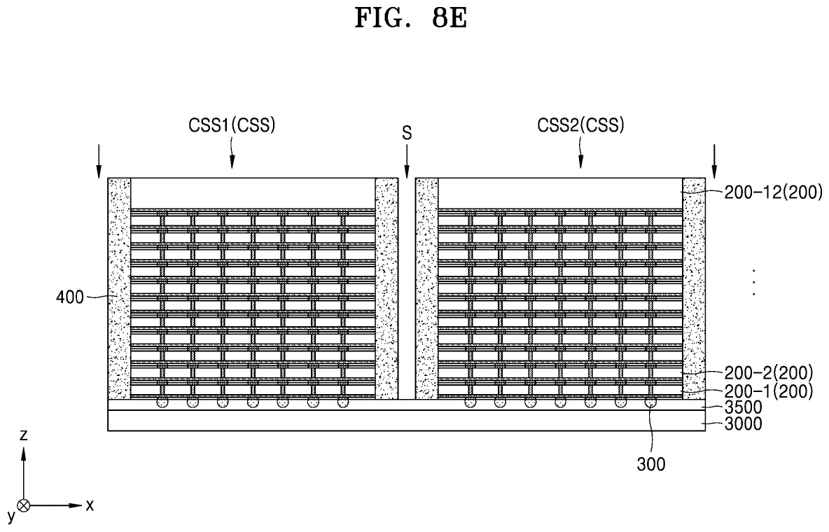

FIGS. 8A to 8E are cross-sectional views of stages in a method of manufacturing a chip stack structure, according to an embodiment. FIGS. 8A to 8E show in detail the stage of FIG. 7B in the method of manufacturing a chip stack structure. FIGS. 1A and 1B are also referred to, and redundant descriptions already given with reference to FIGS. 1A to 7H will be brief or omitted.

Referring to FIG. 8A, in the method of manufacturing a chip stack structure in some example embodiments, memory chips 200 may be stacked on a carrier substrate 3000. The first connection terminal 300 may be arranged on the bottom surface of the first memory chip 200-1. The first memory chip 200-1 may be fixed to an adhesive layer 3500 on the carrier substrate 3000. Each of the memory chips 200 above the first memory chip 200-1 may be stacked on a memory chip 200 directly therebelow through HCB. However, the stacking of the memory chips 200 is not limited to HCB. For example, each of the memory chips 200 may be stacked on a memory chip 200 directly therebelow through the second connection terminal 500.

Referring to FIG. 8B, a certain number of memory chips 200 required for an initial chip stack structure CSSa may be stacked on the carrier substrate 3000. For example, twelve memory chips 200 may be stacked in a single initial chip stack structure CSSa. However, the number of memory chips 200 required for the initial chip stack structure CSSa is not limited to 12. The topmost memory chip 200, e.g., the twelfth memory chip 200-12, may not include the second through electrode 220. The twelfth memory chip 200-12 may be thicker than the other memory chips 200.

Referring to FIG. 8C, after a certain number of memory chips 200 required for the initial chip stack structure CSSa are stacked, an initial inner sealant 400Sa may be formed to seal the initial chip stack structure CSSa on the carrier substrate 3000. The initial inner sealant 400Sa may cover the top surface of the initial chip stack structure CSSa, e.g., the top surface of the twelfth memory chip 200-12.

Referring to FIG. 8D, an upper portion of the initial inner sealant 400Sa may be removed by an inner mold grinding process M/Gi. An inner sealant 400S may be formed by removing the upper portion of the initial inner sealant 400Sa. The top surface of the initial chip stack structure CSSa, e.g., the top surface of the twelfth memory chip 200-12, may be exposed by the inner sealant 400S.

Referring to FIG. 8E, a chip stack structure CSS may be manufactured by singulating the initial chip stack structure CSSa and the inner sealant 400S stacked on the carrier substrate 3000 by using a sawing process S. For example, the chip stack structure CSS may correspond to the chip stack structure CSS of the first semiconductor device 1100 of the semiconductor package 1000 of FIG. 1A.

When the memory chips 200 are stacked through the second connection terminal 500 and the adhesive layer 550 in FIG. 8A, the chip stack structure CSSa of the first semiconductor device 1100a of the semiconductor package 1000a of FIG. 2A may be manufactured in FIG. 8E. When the memory chips 200 are stacked through the second connection terminal 500 in FIG. 8A and an inner sealant is formed through a MUF process in FIG. 8C, the chip stack structure CSSb of the first semiconductor device 1100b of the semiconductor package 1000b of FIG. 3 may be manufactured in FIG. 8E.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

As described herein, any electronic devices and/or portions thereof according to any of the example embodiments may include, may be included in, and/or may be implemented by one or more instances of processing circuitry such as hardware including logic circuits; a hardware/software combination such as a processor executing software; or any combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a DRAM device, storing a program of instructions, and a processor (e.g., CPU) configured to execute the program of instructions to implement the functionality and/or methods performed by some or all of any devices, systems, modules, units, controllers, circuits, architectures, and/or portions thereof according to any of the example embodiments, and/or any portions thereof.

Any or all of the elements described with reference to the figures may communicate with any or all other elements described with reference to figures. For example, any element may engage in one-way and/or two-way and/or broadcast communication with any or all other elements in the figures, to transfer and/or exchange and/or receive information such as but not limited to data and/or commands, in a manner such as in a serial and/or parallel manner, via a bus such as a wireless and/or a wired bus (not illustrated). The information may be in encoded various formats, such as in an analog format and/or in a digital format.

While the inventive concepts have been particularly shown and described with reference to some example embodiments thereof, it will be understood that various changes in form and details may be made therein without departing from the spirit and scope of the following claims.

What is claimed is:

1. A semiconductor package comprising:
an interposer;
a first semiconductor device on the interposer; and
at least one second semiconductor device on the interposer and connected to the interposer through hybrid copper bonding (HCB), the at least one second semiconductor device adjacent to the first semiconductor device,
the at least one second semiconductor device including
a base chip bonded to the interposer through HCB;
a chip stack structure on the base chip and connected to the base chip through a first connection terminal, a plurality of memory chips stacked in the chip stack structure; and
an inner sealant on the base chip and sealing the chip stack structure.

2. The semiconductor package of claim 1, wherein
the at least one second semiconductor device further includes an adhesive layer between the base chip and the chip stack structure, and
the adhesive layer includes a portion protruding from a side surface of one of the base chip and the inner sealant.

3. The semiconductor package of claim 1, wherein the plurality of memory chips are stacked through HCB in the chip stack structure.

4. The semiconductor package of claim 1, wherein the plurality of memory chips are stacked through an inter-chip connection terminal in the chip stack structure.

5. The semiconductor package of claim 4, wherein an adhesive layer or the inner sealant fills between the plurality of memory chips in the chip stack structure.

6. The semiconductor package of claim 1, wherein a top surface of the inner sealant is coplanar with a top surface of the chip stack structure.

7. The semiconductor package of claim 1, wherein
the base chip includes a logic chip, and
the base chip includes a controller configured to control signal transmission between the chip stack structure and an external device.

8. The semiconductor package of claim 1, wherein
each of the plurality of memory chips includes a dynamic random access memory chip, and
the at least one second semiconductor device includes a high-bandwidth memory package.

9. The semiconductor package of claim 1, wherein
the first semiconductor device includes a logic chip, and
the first semiconductor device is stacked on the interposer through a second connection terminal.

10. The semiconductor package of claim 1, further comprising an external sealant on the interposer and sealing the first semiconductor device and the at least one second semiconductor device.

11. A semiconductor package comprising:
an interposer;
a first semiconductor device on the interposer and connected to the interposer through a first connection terminal;
at least one second semiconductor device on the interposer and connected to the interposer through hybrid copper bonding (HCB), the at least one second semiconductor device adjacent to the first semiconductor device; and
an external sealant on the interposer and sealing the first semiconductor device and the at least one second semiconductor device,
the at least one second semiconductor device including
a base chip bonded to the interposer through HCB;
a chip stack structure on the base chip and connected to the base chip through a second connection terminal, a plurality of memory chips stacked in the chip stack structure;
an adhesive layer between the base chip and the chip stack structure; and
an inner sealant on the base chip and sealing the chip stack structure and the adhesive layer.

12. The semiconductor package of claim 11, wherein the adhesive layer includes a portion protruding from a side surface of one of the base chip and the inner sealant.

13. The semiconductor package of claim 11, wherein the plurality of memory chips are stacked through HCB or an inter-chip connection terminal in the chip stack structure.

14. The semiconductor package of claim 11, wherein top surfaces of the external sealant, the inner sealant, the first semiconductor device, and the at least one second semiconductor device are coplanar with one another.

15. The semiconductor package of claim 11, wherein the first semiconductor device includes a logic chip, and the at least one second semiconductor device includes a high-bandwidth memory package.

16. A semiconductor package comprising:
a package substrate;
an interposer on the package substrate;
a first semiconductor device on the interposer and connected to the interposer through a first connection terminal; and
at least one second semiconductor device on the interposer and connected to the interposer through hybrid copper bonding (HCB), the at least one second semiconductor device adjacent to the first semiconductor device,
the at least one second semiconductor device including
a base chip bonded to the interposer through HCB;
a chip stack structure on the base chip and connected to the base chip through a second connection terminal, a plurality of memory chips stacked in the chip stack structure; and
an inner sealant on the base chip and sealing the chip stack structure.

17. The semiconductor package of claim 16, wherein
the at least one second semiconductor device further includes an adhesive layer between the base chip and the chip stack structure, and
the adhesive layer includes a portion protruding from a side surface of one of the base chip and the inner sealant.

18. The semiconductor package of claim 16, wherein the plurality of memory chips are stacked through HCB or an inter-chip connection terminal in the chip stack structure.

19. The semiconductor package of claim 18, wherein, in the chip stack structure,
the plurality of memory chips are stacked through the inter-chip connection terminal, and
one of an adhesive layer and the inner sealant fills between the plurality of memory chips.

20. The semiconductor package of claim 16, wherein
the first semiconductor device includes a logic chip, and
the at least one second semiconductor device includes a high-bandwidth memory package.
